(19) United States
(12) Patent Application Publication
(10) Pub. No.: US 2024/0321763 A1
(43) Pub. Date: Sep. 26, 2024

(54) PACKAGE SUBSTRATE COMPRISING AT LEAST TWO CORE LAYERS

(71) Applicant: QUALCOMM Incorporated, San Diego, CA (US)

(72) Inventors: Hong Bok WE, San Diego, CA (US); Joan Rey Villarba BUOT, Escondido, CA (US); Michelle Yejin KIM, Carlsbad, CA (US)

(21) Appl. No.: 18/189,991

(22) Filed: Mar. 24, 2023

(51) Int. Cl. H01L 23/538; H01L 23/00

(52) U.S. Cl. CPC H01L 23/5389; H01L 23/5383; H01L 23/5384; H01L 24/16; H01L 2224/16227

(57) ABSTRACT

A package comprising a substrate and an integrated device coupled to the substrate. The substrate includes (i) a first cored substrate portion comprising a first core layer comprising a first cavity, a first integrated device located in the first cavity of the first core layer, and a first dielectric layer encapsulating the first integrated device; and (ii) a second cored substrate portion comprising a second core layer comprising a second cavity, a second integrated device located in the second cavity of the second core layer and a second dielectric layer encapsulating the second integrated device.

### FIELD

Various features relate to a package that includes a substrate and an integrated device.

### BACKGROUND

A package may include a substrate and integrated devices. These components are coupled together to provide a package that may perform various functions. The performance of a package and its components may depend on many factors, including the reliability of joints that couple different components together. There is an ongoing need to provide packages that provide improved performances.

### SUMMARY

Various features relate to a package that includes a substrate and an integrated device.

One example provides a substrate that includes (i) a first cored substrate portion comprising a first core layer comprising a first cavity, a first integrated device located in the first cavity of the first core layer, and a first dielectric layer encapsulating the first integrated device; and (ii) a second cored substrate portion comprising a second core layer comprising a second cavity, a second integrated device located in the second cavity of the second core layer and a second dielectric layer encapsulating the second integrated device.

Another example provides a package comprising a substrate and an integrated device coupled to the substrate. The substrate includes (i) a first cored substrate portion comprising a first core layer comprising a first cavity, a first integrated device located in the first cavity of the first core layer, and a first dielectric layer encapsulating the first integrated device; and (ii) a second cored substrate portion comprising a second core layer comprising a second cavity, a second integrated device located in the second cavity of the second core layer and a second dielectric layer encapsulating the second integrated device.

Another example provides a method to fabricate a substrate. Fabricating the substrate comprises providing a first cored substrate portion comprising: a first core layer comprising a first cavity; a first integrated device located in the first cavity of the first core layer; and a first dielectric layer encapsulating the first integrated device. Fabricating the substrate comprises providing a second cored substrate portion comprising: a second core layer comprising a second cavity; a second integrated device located in the second cavity of the second core layer; and a second dielectric layer encapsulating the second integrated device. Fabricating the substrate comprises providing a third dielectric layer. Fabricating the substrate comprises coupling the first cored substrate, the third dielectric layer and the second cored substrate.

Another example provides a method to fabricate a substrate. Fabricating the substrate comprises providing a first cored substrate portion comprising: a first core layer comprising a first cavity; a first integrated device located in the first cavity of the first core layer; and a first dielectric layer encapsulating the first integrated device. Fabricating the substrate comprises providing a second cored substrate portion comprising: a second core layer comprising a second cavity; a second integrated device located in the second cavity of the second core layer; and a second dielectric layer encapsulating the second integrated device. Fabricating the substrate comprises providing a third cored substrate portion comprising a third core layer and a plurality of core interconnects. Fabricating the substrate comprises providing a third dielectric layer and a fourth dielectric layer. Fabricating the substrate comprises coupling the first cored substrate, the third dielectric layer, the third cored substrate portion, the fourth dielectric layer and the second cored substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of an exemplary substrate with at least core layers.

FIG. 2 illustrates a cross sectional profile view of an exemplary substrate with at least core layers.

FIG. 3 illustrates a cross sectional profile view of an exemplary substrate with at least core layers.

FIG. 4 illustrates a cross sectional profile view of an exemplary substrate with at least core layers.

FIG. 5 illustrates a cross sectional profile view of an exemplary package with a substrate with at least core layers.

FIG. 6 illustrates a cross sectional profile view of an exemplary package with a substrate with at least core layers.

FIG. 7 illustrates a cross sectional profile view of an exemplary package with a substrate with at least core layers.

FIG. 8 illustrates a cross sectional profile view of an exemplary package with a substrate with at least core layers.

FIG. 9 illustrates an exemplary sequence for fabricating a cored substrate portion.

FIGS. 10A-10B illustrate an exemplary sequence for fabricating a cored substrate portion.

FIGS. 11A-11B illustrate an exemplary sequence for fabricating a cored substrate portion.

FIG. 12 illustrates an exemplary flow diagram of a method for fabricating a cored substrate portion.

FIGS. 13A-13C illustrate an exemplary sequence for fabricating a substrate with several cored substrate portions.

FIGS. 14A-14E illustrate an exemplary sequence for fabricating a substrate with several cored substrate portions.

FIG. 15 illustrates an exemplary flow diagram of a method for fabricating a substrate with several cored substrate portions.

FIG. 16 illustrates various electronic devices that may integrate a die, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate (e.g., package substrate). The substrate includes (i) a first cored substrate portion comprising a first core layer comprising a first cavity, a first integrated device located in the first cavity of the first core layer, and a first dielectric layer encapsulating the first integrated device; and (ii) a second cored substrate portion comprising a second core layer comprising a second cavity, a second integrated device located in the second cavity of the second core layer and a second dielectric layer encapsulating the second integrated device. The package also includes a third integrated device coupled to the substrate through a plurality of solder interconnects. The first integrated device and/or the second integrated device may include deep trench capacitors. The use of a substrate that includes several core layers helps provides components that are close to an integrated device to the substrate, which can help improve the performance of the integrated device and/or the package. Moreover, the use of several core layers helps reduce warpage of the substrate since using two or more core layers helps provide a symmetric structure in the substrate. Reducing the warpage of the substrate helps with the reliability of the joints between the third integrated device and the substrate, which can help improve the performance of the package and the reliability of the package.

### Exemplary Package Comprising a Substrate With at Least Two Core Layers

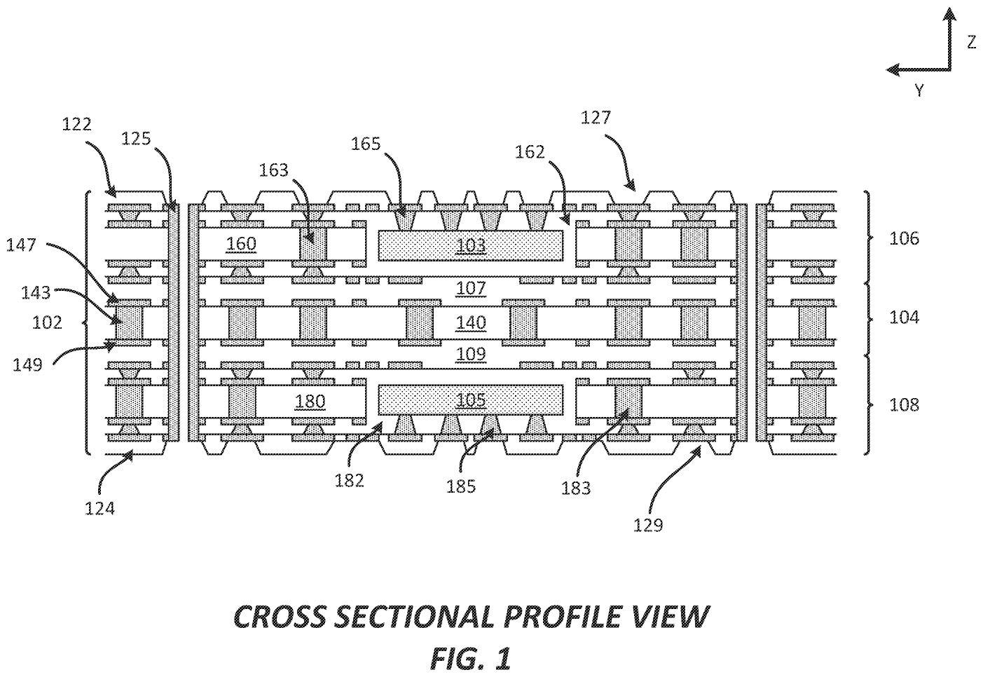

FIG. 1 illustrates a substrate 102 that includes at least two core layers. The substrate 102 may be a package substrate that is implemented as part of a package. The substrate 102 includes a cored substrate portion 104 , a cored substrate portion 106 and a cored substrate portion 108. The cored substrate portion 106 may be a first cored substrate portion. The cored substrate portion 108 may be a second cored substrate portion. The cored substrate portion 104 may be located between the cored substrate portion 106 and the cored substrate portion 108.

The cored substrate portion 106 includes a core layer 160, at least one dielectric layer 162, a plurality of core interconnects 163 and a plurality of interconnects 165. The core layer 160 may be a first core layer. The at least one dielectric layer 162 may be at least one first dielectric layer. The plurality of core interconnects 163 may include a first plurality of core interconnects. The plurality of core interconnects 163 may be located in the core layer 160. The plurality of interconnects 165 may include a first plurality of interconnects. The plurality of interconnects 165 may be located in the at least one dielectric layer 162. The plurality of interconnects 165 may be coupled to the plurality of core interconnects 163.

The core layer 160 may include a cavity. An integrated device 103 may be embedded in the cored substrate portion 106. The integrated device 103 may be located at least in the cored substrate portion 106. For example, the integrated device 103 may be located in the cavity of the core layer 160. Some of the at least one dielectric layer 162 may be located in the cavity of the core layer 160. The at least one dielectric layer 162 may surround and touch the integrated device 103. For example, the at least one dielectric layer 162 may be coupled to and touch a front side of the integrated device 103, a back side of the integrated device 103 and/or a side surface of the integrated device 103. The integrated device 103 may be considered part of the cored substrate portion 106. The integrated device 103 may be a first integrated device. Some interconnects from the plurality of interconnects 165 may be coupled to and touching the front side of the integrated device 103 (e.g., coupled to touching pads of the integrated device 103). In some implementations, the integrated device 103 may include a deep trench capacitor (e.g., deep trench capacitor device).

The cored substrate portion 108 includes a core layer 180, at least one dielectric layer 182, a plurality of core interconnects 183 and a plurality of interconnects 185. The core layer 180 may be a second core layer. The at least one dielectric layer 182 may be at least one second dielectric layer. The plurality of core interconnects 183 may include a second plurality of core interconnects. The plurality of core interconnects 183 may be located in the core layer 180. The plurality of interconnects 185 may include a second plurality of interconnects. The plurality of interconnects 185 may be located in the at least one dielectric layer 182. The plurality of interconnects 185 may be coupled to the plurality of core interconnects 183.

The core layer 180 may include a cavity. An integrated device 105 may be embedded in the cored substrate portion 108. The integrated device 105 may be located at least in the cored substrate portion 108. For example, the integrated device 105 may be located in the cavity of the core layer 180. Some of the at least one dielectric layer 182 may be located in the cavity of the core layer 180. The at least one dielectric layer 182 may surround and touch the integrated device 105. For example, the at least one dielectric layer 182 may be coupled to and touch a front side of the integrated device 105, a back side of the integrated device 105 and/or a side surface of the integrated device 105. The integrated device 105 may be considered part of the cored substrate portion 108. The integrated device 105 may be a second integrated device. Some interconnects from the plurality of interconnects 185 may be coupled to and touching the front side of the integrated device 105 (e.g., coupled to touching pads of the integrated device 105). In some implementations, the integrated device 105 may include a deep trench capacitor (e.g., deep trench capacitor device).

The cored substrate portion 104 includes a core layer 140, at least one dielectric layer 107, at least one dielectric layer 109, a plurality of core interconnects 143, a plurality of interconnects 147 and a plurality of interconnects 149. The core layer 140 may be a third core layer. The plurality of core interconnects 143 may include a third plurality of core interconnects. The plurality of core interconnects 143 may be located in the core layer 140. The plurality of interconnects 147 may be located in the at least one dielectric layer 107. The plurality of interconnects 149 may be located in the at least one dielectric layer 109. The plurality of interconnects 147 may be coupled to the plurality of core interconnects 143. The plurality of interconnects 149 may be coupled to the plurality of core interconnects 143.

The cored substrate portion 104 may be coupled to the cored substrate portion 106 through the at least one dielectric layer 107. The at least one dielectric layer 107 may be considered part of the cored substrate portion 104 and/or the cored substrate portion 106. The at least one dielectric layer 107 may be an at least one third dielectric layer. The cored substrate portion 104 may be coupled to the cored substrate portion 108 through the at least one dielectric layer 109. The at least one dielectric layer 109 may be considered part of the cored substrate portion 104 and/or the cored substrate portion 108. The at least one dielectric layer 109 may be an at least one fourth dielectric layer. The cored substrate portion 104 is located between the cored substrate portion 106 and the cored substrate portion 108. The core layer 140 is located between the core layer 160 and the core layer 180.

The substrate 102 also includes a plurality of via interconnects 125 that extends through the substrate 102. The plurality of via interconnects 125 may be a plurality of through substrate vias. The plurality of via interconnects 125 may extend through the cored substrate portion 106, the cored substrate portion 104 and the cored substrate portion 108. The plurality of via interconnects 125 may extend through the at least one dielectric layer 162, the core layer 160, the at least one dielectric layer 107, the core layer 140, the at least one dielectric layer 109, the core layer 180 and the least one dielectric layer 182. The at least one dielectric layer 162, the at least one dielectric layer 107, the at least one dielectric layer 109, and/or the at least one dielectric layer 182 may include the same material or different materials. For example, the at least one dielectric layer 162, the at least one dielectric layer 107, the at least one dielectric layer 109, and/or the at least one dielectric layer 182 may include prepreg.

The plurality of via interconnects 125 may be configured to be electrically coupled to the plurality of interconnects 165, the plurality of interconnects 147, the plurality of interconnects 149, and/or the plurality of interconnects 185. The plurality of via interconnects 125 may be configured to be electrically coupled to the plurality of core interconnects 163, the plurality of core interconnects 143, and/or the plurality of core interconnects 183. The plurality of via interconnects 125 may be formed in and/or coupled to the side walls of a plurality of cavities that extend through the substrate 102.

The substrate 102 also includes a solder resist layer 122 and a solder resist layer 124. The solder resist layer 122 may be located over (e.g., above) a surface of the cored substrate portion 106. The solder resist layer 122 may include a plurality of openings 127. The solder resist layer 124 may be located over (e.g., below) a surface of the cored substrate portion 108. The solder resist layer 124 may include a plurality of openings 129.

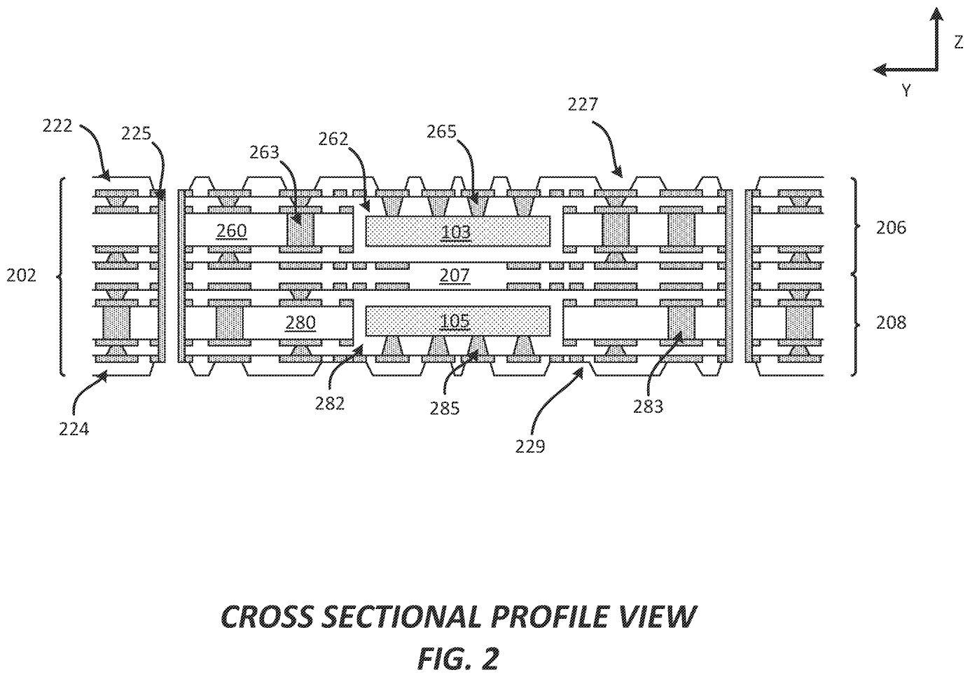

FIG. 2 illustrates a substrate 202 that includes at least two core layers. The substrate 202 may be a package substrate that is implemented as part of a package. The substrate 202 includes a cored substrate portion 206 and a cored substrate portion 208. The cored substrate portion 206 may be a first cored substrate portion. The cored substrate portion 208 may be a second cored substrate portion.

The cored substrate portion 206 includes a core layer 260, at least one dielectric layer 262, a plurality of core interconnects 263 and a plurality of interconnects 265. The core layer 260 may be a first core layer. The at least one dielectric layer 262 may be at least one first dielectric layer. The plurality of core interconnects 263 may include a first plurality of core interconnects. The plurality of core interconnects 263 may be located in the core layer 260. The plurality of interconnects 265 may include a first plurality of interconnects. The plurality of interconnects 265 may be located in the at least one dielectric layer 262. The plurality of interconnects 265 may be coupled to the plurality of core interconnects 263.

The core layer 260 may include a cavity. An integrated device 103 may be embedded in the cored substrate portion 206. The integrated device 103 may be located at least in the cored substrate portion 206. For example, the integrated device 103 may be located in the cavity of the core layer 260. Some of the at least one dielectric layer 262 may be located in the cavity of the core layer 260. The at least one dielectric layer 262 may surround and touch the integrated device 103. For example, the at least one dielectric layer 262 may be coupled to and touch a front side of the integrated device 103, a back side of the integrated device 103 and/or a side surface of the integrated device 103. The integrated device 103 may be considered part of the cored substrate portion 206. The integrated device 103 may be a first integrated device. Some interconnects from the plurality of interconnects 265 may be coupled to and touching the front side of the integrated device 103 (e.g., coupled to touching pads of the integrated device 103). In some implementations, the integrated device 103 may include a deep trench capacitor (e.g., deep trench capacitor device).

The cored substrate portion 208 includes a core layer 280, at least one dielectric layer 282, a plurality of core interconnects 283 and a plurality of interconnects 285. The core layer 280 may be a second core layer. The at least one dielectric layer 282 may be at least one second dielectric layer. The plurality of core interconnects 283 may include a second plurality of core interconnects. The plurality of core interconnects 283 may be located in the core layer 280. The plurality of interconnects 285 may include a second plurality of interconnects. The plurality of interconnects 285 may be located in the at least one dielectric layer 282. The plurality of interconnects 285 may be coupled to the plurality of core interconnects 283.

The core layer 280 may include a cavity. An integrated device 105 may be embedded in the cored substrate portion 208. The integrated device 105 may be located at least in the cored substrate portion 208. For example, the integrated device 105 may be located in the cavity of the core layer 280. Some of the at least one dielectric layer 282 may be located in the cavity of the core layer 280. The at least one dielectric layer 282 may surround and touch the integrated device 105. For example, the at least one dielectric layer 282 may be coupled to and touch a front side of the integrated device 105, a back side of the integrated device 105 and/or a side surface of the integrated device 105. The integrated device 105 may be considered part of the cored substrate portion 208. The integrated device 105 may be a second integrated device. Some interconnects from the plurality of interconnects 285 may be coupled to and touching the front side of the integrated device 105 (e.g., coupled to touching pads of the integrated device 105). In some implementations, the integrated device 105 may include a deep trench capacitor (e.g., deep trench capacitor device).

The cored substrate portion 206 may be coupled to the cored substrate portion 208 through the at least one dielectric layer 207. The at least one dielectric layer 207 may be considered part of the cored substrate portion 206 and/or the cored substrate portion 208. The at least one dielectric layer 207 may be an at least one third dielectric layer.

The substrate 202 also includes a plurality of via interconnects 225 that extends through the substrate 202. The plurality of via interconnects 225 may be a plurality of through substrate vias. The plurality of via interconnects 225 may extend through the cored substrate portion 206 and the cored substrate portion 208. The plurality of via interconnects 225 may extend through the at least one dielectric layer 262, the core layer 260, the at least one dielectric layer 207, the core layer 280 and the at least one dielectric layer 282. The at least one dielectric layer 262, the at least one dielectric layer 207, and/or the at least one dielectric layer 282 may include the same material or different materials. For example, the at least one dielectric layer 262, the at least one dielectric layer 207 and/or the at least one dielectric layer 282 may include prepreg.

The plurality of via interconnects 225 may be configured to be electrically coupled to the plurality of interconnects 265 and/or the plurality of interconnects 285. The plurality of via interconnects 225 may be configured to be electrically coupled to the plurality of core interconnects 263 and/or the plurality of core interconnects 283. The plurality of via interconnects 225 may be formed in and/or coupled to the side walls of a plurality of cavities that extend through the substrate 202.

The substrate 202 also includes a solder resist layer 222 and a solder resist layer 224. The solder resist layer 222 may be located over (e.g., above) a surface of the cored substrate portion 206. The solder resist layer 222 may include a plurality of openings 227. The solder resist layer 124 may be located over (e.g., below) a surface of the cored substrate portion 208. The solder resist layer 224 may include a plurality of openings 229.

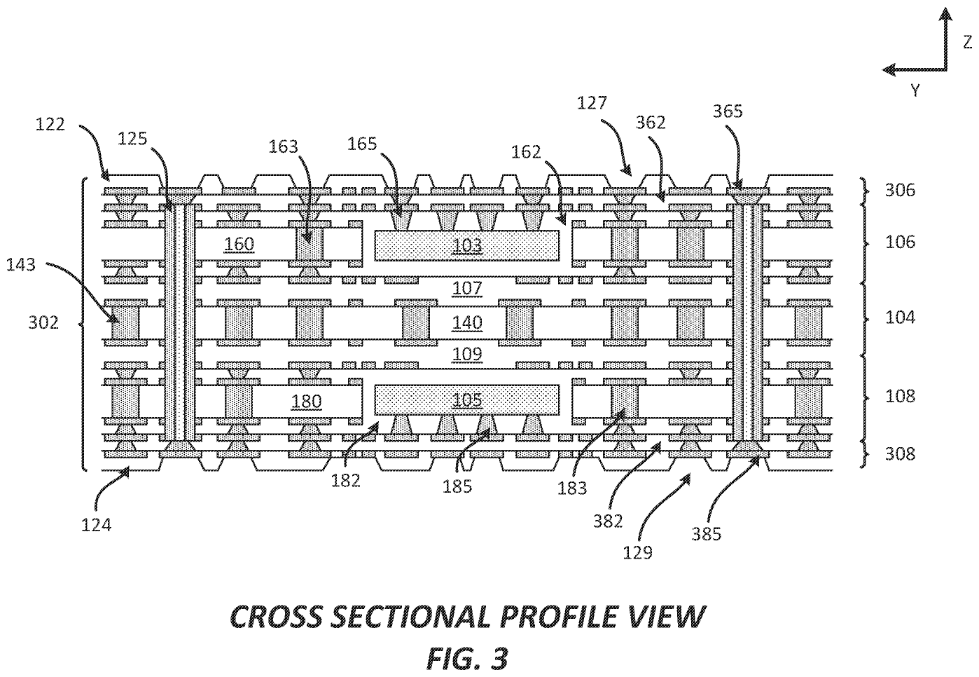

FIG. 3 illustrates a substrate 302 that includes at least two core layers. The substrate 302 may be a package substrate that is implemented as part of a package. The substrate 302 is similar to the substrate 102, and thus may include similar components arranged in a similar manner, as described for the substrate 102. The substrate 302 includes a cored substrate portion 104, a cored substrate portion 106, a cored substrate portion 108, a metallization portion 306 and a metallization portion 308. The cored substrate portion 106 may be a first cored substrate portion. The cored substrate portion 108 may be a second cored substrate portion. The cored substrate portion 104 may be located between the cored substrate portion 106 and the cored substrate portion 108. The metallization portion 306 may be a first metallization portion. The metallization portion 308 may be a second metallization portion. The metallization portion 306 is coupled to the cored substrate portion 106. In some implementations, the metallization portion 306 may be considered part of the cored substrate portion 106. The metallization portion 308 is coupled to the cored substrate portion 108. In some implementations, the metallization portion 308 may be considered part of the cored substrate portion 108.

The metallization portion 306 includes at least one dielectric layer 362 and a plurality of interconnects 365. The plurality of interconnects 365 may include a plurality of metallization interconnects. The plurality of interconnects 365 is configured to be electrically coupled to the plurality of interconnects 165.

The metallization portion 308 includes at least one dielectric layer 382 and a plurality of interconnects 385. The plurality of interconnects 385 may include a plurality of metallization interconnects. The plurality of interconnects 385 is configured to be electrically coupled to the plurality of interconnects 185.

The plurality of via interconnects 125 may be configured to be electrically coupled to the plurality of interconnects 165, the plurality of interconnects 147, the plurality of interconnects 149, the plurality of interconnects 185, the plurality of interconnects 365 and/or the plurality of interconnects 385. The plurality of via interconnects 125 may be formed in and/or coupled to the side walls of a plurality of cavities that extend through the substrate 102. A filler 325 may be located in the plurality of cavities that includes the plurality of via interconnects 125.

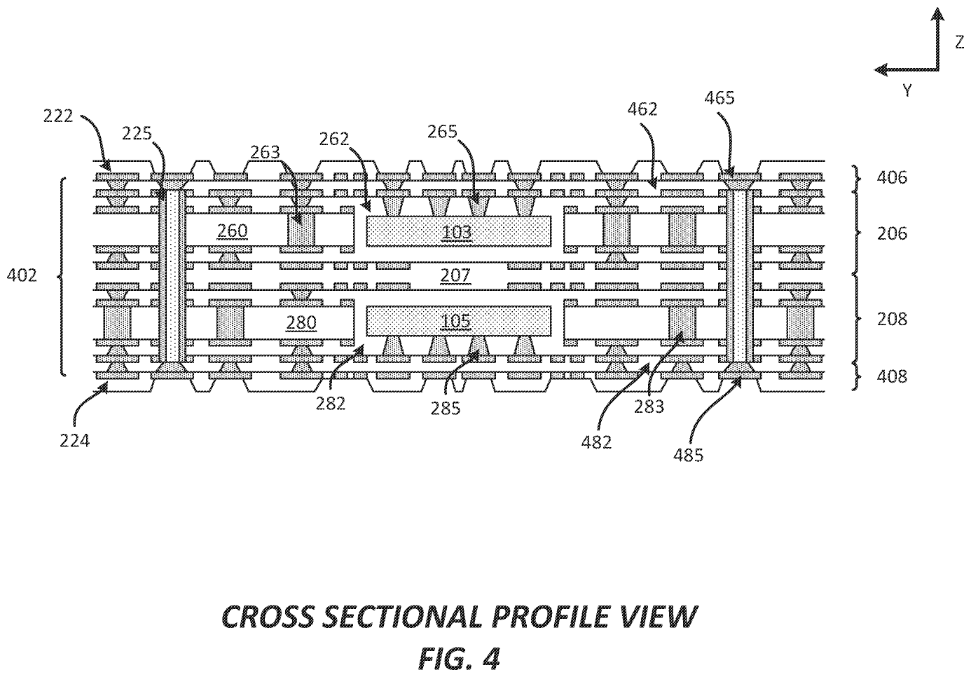

FIG. 4 illustrates a substrate 402 that includes at least two core layers. The substrate 402 may be a package substrate that is implemented as part of a package. The substrate 402 is similar to the substrate 202, and thus may include similar components arranged in a similar manner as described for the substrate 202. The substrate 402 includes a cored substrate portion 206, a cored substrate portion 208, a metallization portion 406 and a metallization portion 408. The cored substrate portion 106 may be a first cored substrate portion. The cored substrate portion 108 may be a second cored substrate portion. The cored substrate portion 106 may be coupled to the cored substrate portion 108. The metallization portion 406 may be a first metallization portion. The metallization portion 408 may be a second metallization portion. The metallization portion 406 is coupled to the cored substrate portion 206. In some implementations, the metallization portion 406 may be considered part of the cored substrate portion 206. The metallization portion 408 is coupled to the cored substrate portion 208. In some implementations, the metallization portion 408 may be considered part of the cored substrate portion 208.

The metallization portion 406 includes at least one dielectric layer 462 and a plurality of interconnects 465. The plurality of interconnects 465 may include a plurality of metallization interconnects. The plurality of interconnects 465 is configured to be electrically coupled to the plurality of interconnects 265.

The metallization portion 408 includes at least one dielectric layer 482 and a plurality of interconnects 485. The plurality of interconnects 485 may include a plurality of metallization interconnects. The plurality of interconnects 485 is configured to be electrically coupled to the plurality of interconnects 285.

The plurality of via interconnects 225 may be configured to be electrically coupled to the plurality of interconnects 265, the plurality of interconnects 285, the plurality of interconnects 465 and/or the plurality of interconnects 485. The plurality of via interconnects 225 may be formed in and/or coupled to the side walls of a plurality of cavities that extend through the substrate 102. A filler 425 may be located in the plurality of cavities that includes the plurality of via interconnects 225.

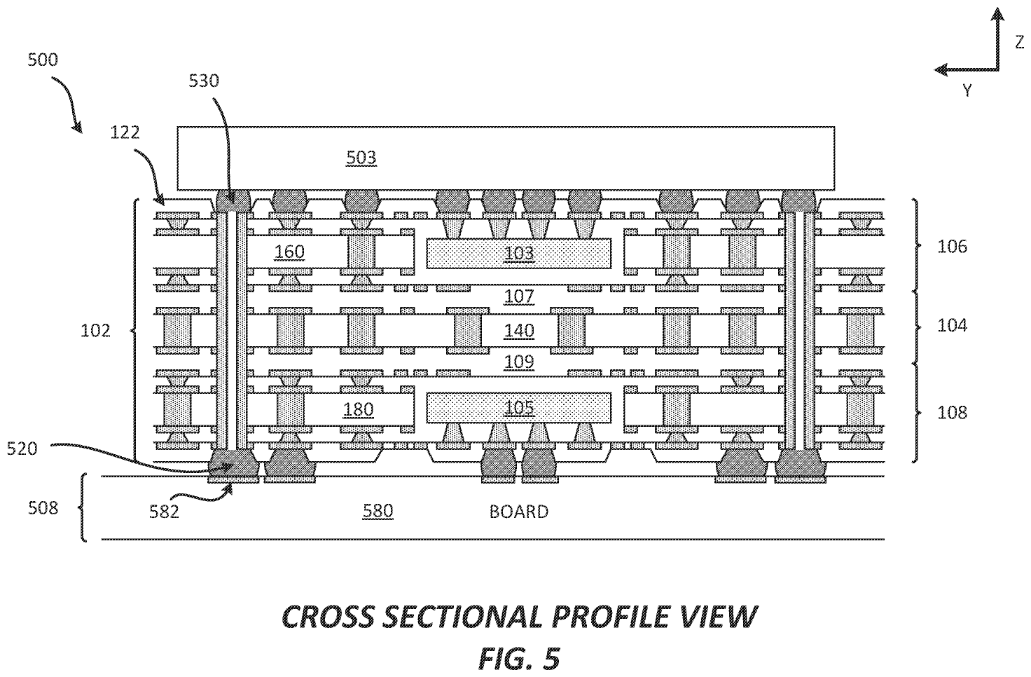

FIG. 5 illustrates a package 500 that includes an integrated device and a substrate with at least two core layers. The package 500 is coupled to the board 508 through a plurality of solder interconnects 520. The board 508 includes at least one board dielectric layer 580 and a plurality of board interconnects 582. The board 508 may include a printed circuit board (PCB). The package 500 includes the substrate 102 and an integrated device 503. The integrated device 503 is coupled to the substrate 102 through a plurality of solder interconnects 530. For example, the integrated device 503 is coupled to the cored substrate portion 106 of the substrate 102, through the plurality of solder interconnects 530. The plurality of solder interconnects 530 may be coupled to the plurality of via interconnects 125 and/or the plurality of interconnects 165.

An electrical path between the board 508 and the integrated device 503 may include a board interconnect from the plurality of board interconnects 582, a solder interconnect from the plurality of solder interconnects 520, a via interconnect from the plurality of via interconnects 125, and a solder interconnect from the plurality of solder interconnects 530.

In some implementations, an electrical path between the board 508 and the integrated device 503 may include a board interconnect from the plurality of board interconnects 582, a solder interconnect from the plurality of solder interconnects 520, a via interconnect from the plurality of via interconnects 125, at least one interconnect from the plurality of interconnects 185, at least one core interconnect from the plurality of core interconnects 183, at least one interconnect from the plurality of interconnects 149, at least one core interconnect from the plurality of core interconnects 143, at least one interconnect from the plurality of interconnects 147, at least one interconnect from the plurality of interconnects 165, at least one core interconnect from the plurality of core interconnects 163, and/or a solder interconnect from the plurality of solder interconnects 530.

In some implementations, an electrical path between the integrated device 103 and the integrated device 503 may include an interconnect from the plurality of interconnects 165 and a solder interconnect from the plurality of solder interconnects 530.

In some implementations, an electrical path between the integrated device 105 and the integrated device 503 may include an interconnect from the plurality of 185, a via interconnect from the plurality of via interconnects 125, and a solder interconnect from the plurality of solder interconnects 530.

In some implementations, an electrical path between the integrated device 105 and the integrated device 503 may include at least one interconnect from the plurality of interconnects 185, a via interconnect from the plurality of via interconnects 125, at least one core interconnect from the plurality of core interconnects 183, at least one interconnect from the plurality of interconnects 149, at least one core interconnect from the plurality of core interconnects 143, at least one interconnect from the plurality of interconnects 147, at least one interconnect from the plurality of interconnects 165, at least one core interconnect from the plurality of core interconnects 163, and/or a solder interconnect from the plurality of solder interconnects 530.

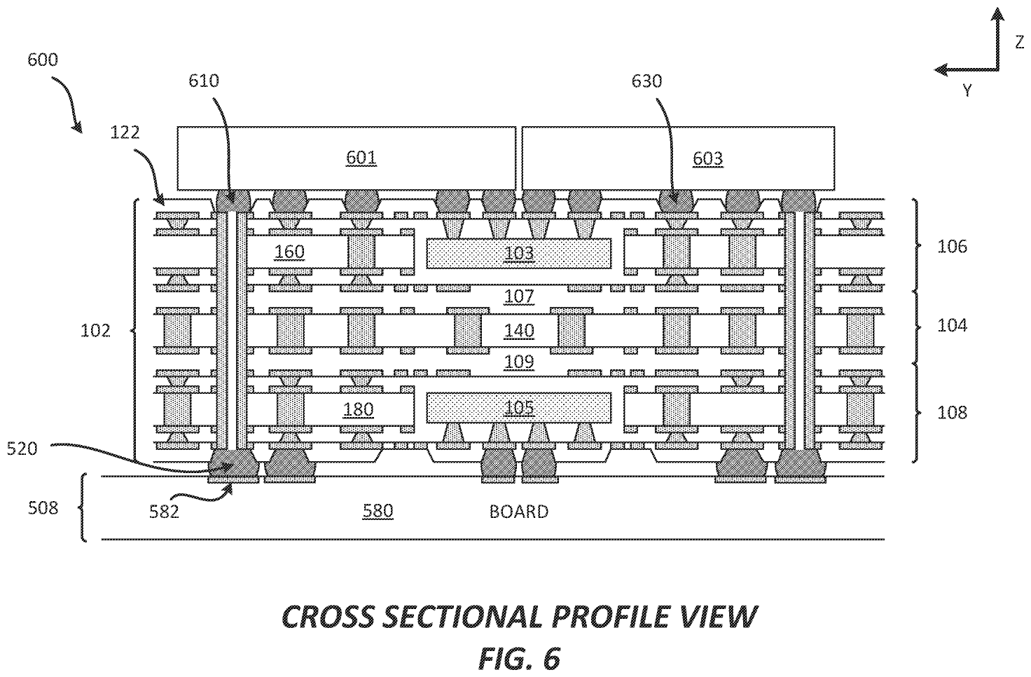

FIG. 6 illustrates a package 600 that includes several integrated devices and a substrate with at least two core layers. The package 600 is coupled to the board 508 through a plurality of solder interconnects 520. The board 508 includes at least one board dielectric layer 580 and a plurality of board interconnects 582. The board 508 may include a printed circuit board (PCB). The package 600 includes the substrate 102, an integrated device 601 and an integrated device 603.

The integrated device 601 is coupled to the substrate 102 through a plurality of solder interconnects 610. For example, the integrated device 601 is coupled to the cored substrate portion 106 of the substrate 102, through the plurality of solder interconnects 610. The plurality of solder interconnects 610 may be coupled to the plurality of via interconnects 125 and/or the plurality of interconnects 165. The integrated device 603 is coupled to the substrate 102 through a plurality of solder interconnects 630. For example, the integrated device 603 is coupled to the cored substrate portion 106 of the substrate 102, through the plurality of solder interconnects 630. The plurality of solder interconnects 630 may be coupled to the plurality of via interconnects 125 and/or the plurality of interconnects 165.

In some implementations, the integrated device 601 and/or the integrated device 603 may each be a chiplet. In some implementations, the integrated device 103 and/or the integrated device 103 may each be a chiplet. In some implementations, one of more of integrated devices (e.g., 601, 603, 103, 105) described in the disclosure may be fabricated using the same technology node or two or more different technology nodes. For example, a chiplet (e.g., 601) may be fabricated using a first technology node, and another chiplet (e.g., 603) may be fabricated using a second technology node that is not as advanced as the first technology node. In such an example, a chiplet (e.g., 601) may include components (e.g., interconnects, transistors) that have a first minimum size, and the other chiplet (e.g., 603) may include components (e.g., interconnects, transistors) that have a second minimum size, where the second minimum size is greater than the first minimum size. In some implementations, the integrated device 601 and the integrated device 603 of a package, may be fabricated using the same technology node or different technology nodes. In some implementations, a chiplet (e.g., 601) and another chiplet (e.g., 603) of a package, may be fabricated using the same technology node or different technology nodes.

The integrated device 601 and the integrated device 601 may be configured to perform different operations. The integrated device 601 is configured to be electrically coupled to the integrated device 603 through the at least one electrical path that includes at least one solder interconnect from the plurality of solder interconnects 610, interconnects from the plurality of interconnects 165 and at least one solder interconnect from the plurality of solder interconnects 630.

In some implementations, the integrated device 103 may be configured to operate as a bridge in the substrate 102. The integrated device 601 is configured to be electrically coupled through the at least one electrical path that includes at least one solder interconnect from the plurality of solder interconnects 610, interconnects from the plurality of interconnects 165, the integrated device 103, other interconnects from the plurality of interconnects 165, and at least one solder interconnect from the plurality of solder interconnects 630.

In some implementations, the integrated device 601 may be a first chiplet and the integrated device 603 may be a second chiplet. The integrated device 601 may be configured to perform a first plurality of functions and/or operations. The integrated device 603 may be configured to perform a second plurality of functions and/or operations. The second plurality of functions and/or operations includes at least one function and/or operation that is different from the first plurality of functions and/or operations. In some implementations, the integrated device 601 may be fabricated using a first technology node, and the integrated device 603 may be fabricated using a second technology node that is not as advanced as the first technology node. In some implementations, the integrated device 103 may be fabricated using a third technology node that is different from the first technology node and/or the second technology node.

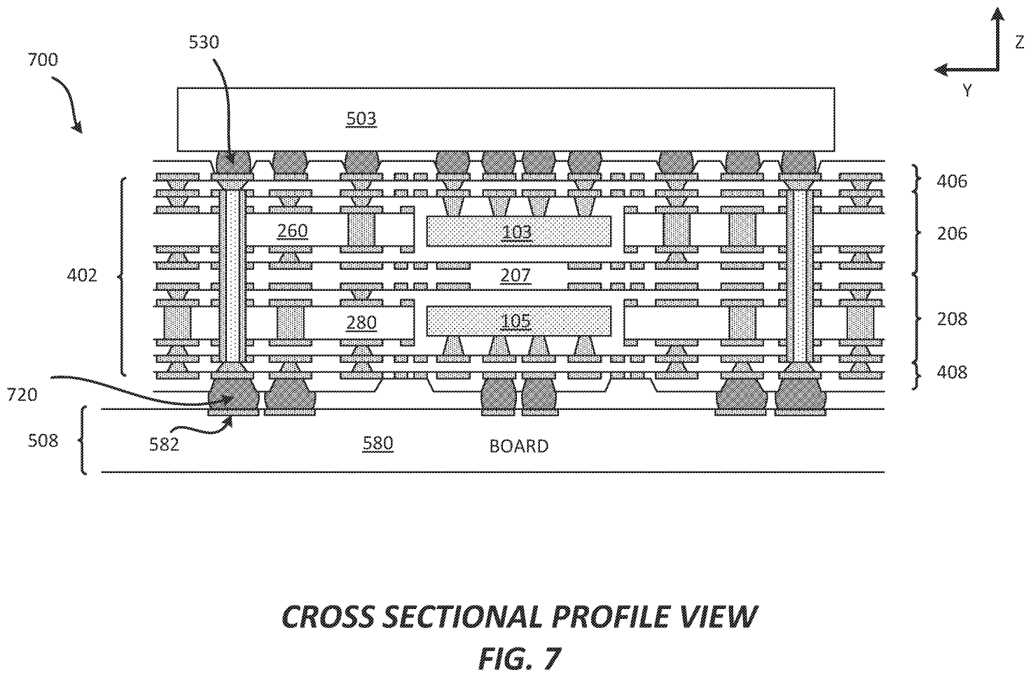

FIG. 7 illustrates a package 700 that includes an integrated device and a substrate with at least two core layers. The package 700 is coupled to the board 508 through a plurality of solder interconnects 720. The board 508 includes at least one board dielectric layer 580 and a plurality of board interconnects 582. The board 508 may include a printed circuit board (PCB). The package 700 includes the substrate 402 and an integrated device 503. The integrated device 503 is coupled to the substrate 402 through a plurality of solder interconnects 530. For example, the integrated device 503 is coupled to the metallization portion 406 of the substrate 402, through the plurality of solder interconnects 530. The plurality of solder interconnects 530 may be coupled to the plurality of interconnects 465.

An electrical path between the board 508 and the integrated device 503 may include a board interconnect from the plurality of board interconnects 582, a solder interconnect from the plurality of solder interconnects 720, at least one interconnect from the plurality of interconnects 485, a via interconnect from the plurality of via interconnects 225, at least one interconnect from the plurality of interconnects 465, and a solder interconnect from the plurality of solder interconnects 530.

In some implementations, an electrical path between the board 508 and the integrated device 503 may include a board interconnect from the plurality of board interconnects 582, a solder interconnect from the plurality of solder interconnects 720, at least one interconnect from the plurality of interconnects 485, a via interconnect from the plurality of via interconnects 225, at least one interconnect from the plurality of interconnects 285, at least one core interconnect from the plurality of core interconnects 283, at least one interconnect from the plurality of interconnects 265, at least one core interconnect from the plurality of core interconnects 263, at least one interconnect from the plurality of interconnects 465, and/or a solder interconnect from the plurality of solder interconnects 230.

In some implementations, an electrical path between the integrated device 103 and the integrated device 503 may include an interconnect from the plurality of interconnects 265, at least one interconnect from the plurality of interconnects 465, and a solder interconnect from the plurality of solder interconnects 230.

In some implementations, an electrical path between the integrated device 105 and the integrated device 503 may include an interconnect from the plurality of 185, at least one interconnect from the plurality of interconnects 485, a via interconnect from the plurality of via interconnects 225, at least one interconnect from the plurality of interconnects 465, and a solder interconnect from the plurality of solder interconnects 530.

In some implementations, an electrical path between the integrated device 105 and the integrated device 503 may include at least one interconnect from the plurality of interconnects 285, at least one interconnect from the plurality of interconnects 485, a via interconnect from the plurality of via interconnects 225, at least one core interconnect from the plurality of core interconnects 283, at least one interconnect from the plurality of interconnects 265, at least one core interconnect from the plurality of core interconnects 263, at least one interconnect from the plurality of interconnects 465, and/or a solder interconnect from the plurality of solder interconnects 530.

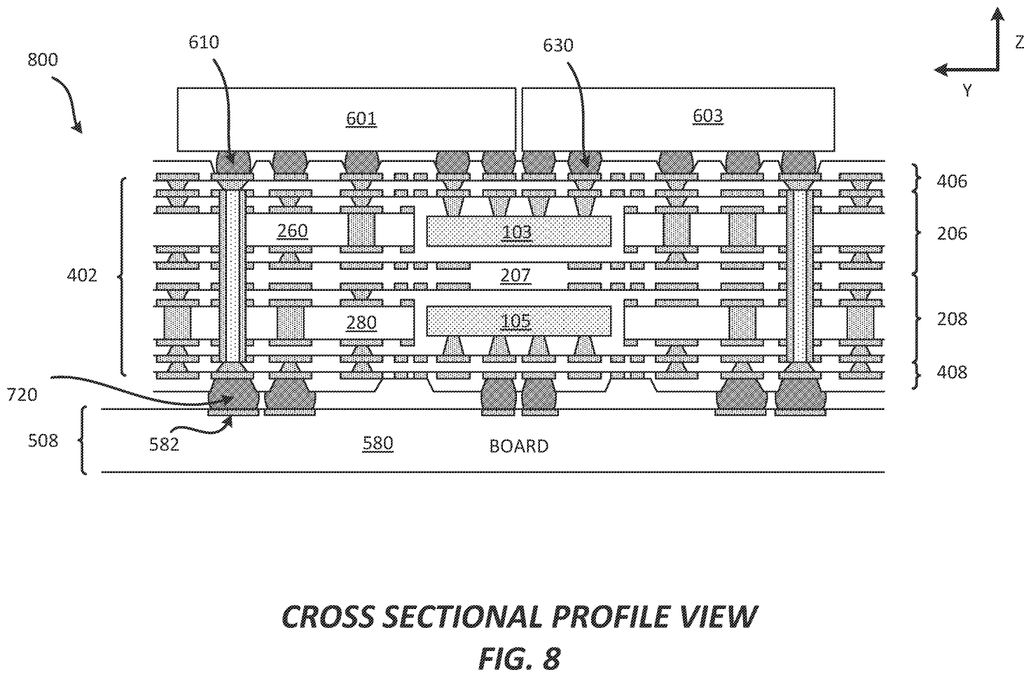

FIG. 8 illustrates a package 800 that includes several integrated devices and a substrate with at least two core layers. The package 800 is coupled to the board 508 through a plurality of solder interconnects 720. The board 508 includes at least one board dielectric layer 580 and a plurality of board interconnects 582. The board 508 may include a printed circuit board (PCB). The package 600 includes the substrate 402, an integrated device 601 and an integrated device 603.

The integrated device 601 is coupled to the substrate 402 through a plurality of solder interconnects 610. For example, the integrated device 601 is coupled to the cored substrate portion 106 of the substrate 102, through the plurality of solder interconnects 610. The plurality of solder interconnects 610 may be coupled to the plurality of interconnects 465. The integrated device 603 is coupled to the substrate 102 through a plurality of solder interconnects 630. For example, the integrated device 603 is coupled to the cored substrate portion 106 of the substrate 102, through the plurality of solder interconnects 630. The plurality of solder interconnects 630 may be coupled the plurality of interconnects 465.

As mentioned above, in some implementations, the integrated device 601 and/or the integrated device 603 may each be a chiplet. In some implementations, the integrated device 103 and/or the integrated device 103 may each be a chiplet. In some implementations, one of more of integrated devices (e.g., 601, 603, 103, 105) described in the disclosure may be fabricated using the same technology node or two or more different technology nodes. For example, a chiplet (e.g., 601) may be fabricated using a first technology node, and another chiplet (e.g., 603) may be fabricated using a second technology node that is not as advanced as the first technology node. In such an example, a chiplet (e.g., 601) may include components (e.g., interconnects, transistors) that have a first minimum size, and the other chiplet (e.g., 603) may include components (e.g., interconnects, transistors) that have a second minimum size, where the second minimum size is greater than the first minimum size. In some implementations, the integrated device 601 and the integrated device 603 of a package, may be fabricated using the same technology node or different technology nodes. In some implementations, a chiplet (e.g., 601) and another chiplet (e.g., 603) of a package, may be fabricated using the same technology node or different technology nodes.

The integrated device 601 is configured to be electrically coupled to the integrated device 603 through the at least one electrical path that includes at least one solder interconnect from the plurality of solder interconnects 610, interconnects from the plurality of interconnects 465 and at least one solder interconnect from the plurality of solder interconnects 630.

In some implementations, the integrated device 601 is configured to be electrically coupled to the integrated device 603 through the at least one electrical path that includes at least one solder interconnect from the plurality of solder interconnects 610, interconnects from the plurality of interconnects 465, interconnects from the plurality of interconnects 265 and at least one solder interconnect from the plurality of solder interconnects 630.

In some implementations, the integrated device 103 may be configured to operate as a bridge in the substrate 402. The integrated device 601 is configured to be electrically coupled through the at least one electrical path that includes at least one solder interconnect from the plurality of solder interconnects 610, interconnects from the plurality of interconnects 465, interconnects from the plurality of interconnects 165, the integrated device 103, other interconnects from the plurality of interconnects 165, other interconnects from the plurality of interconnects 465, and at least one solder interconnect from the plurality of solder interconnects 630.

An integrated device (e.g., 501, 601, 603, 103, 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SIC) based integrated device, a memory, power management processor, and/or combinations thereof. An integrated device (e.g., 501, 601, 603, 103, 105) may include at least one electronic circuit (e.g., first electronic circuit, second electronic circuit, etc. . . . ). An integrated device may include transistors. An integrated device may be an example of an electrical component and/or electrical device. In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Thus, for example, a single integrated device may be split into several chiplets. As mentioned above, using several chiplets that perform several functions may reduce the overall cost of a package relative to using a single chip to perform all of the functions of a package. In some implementations, one or more of the chiplets and/or one or more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, an integrated device and another integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advance technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

### Exemplary Sequence for Fabricating a Cored Substrate Portion

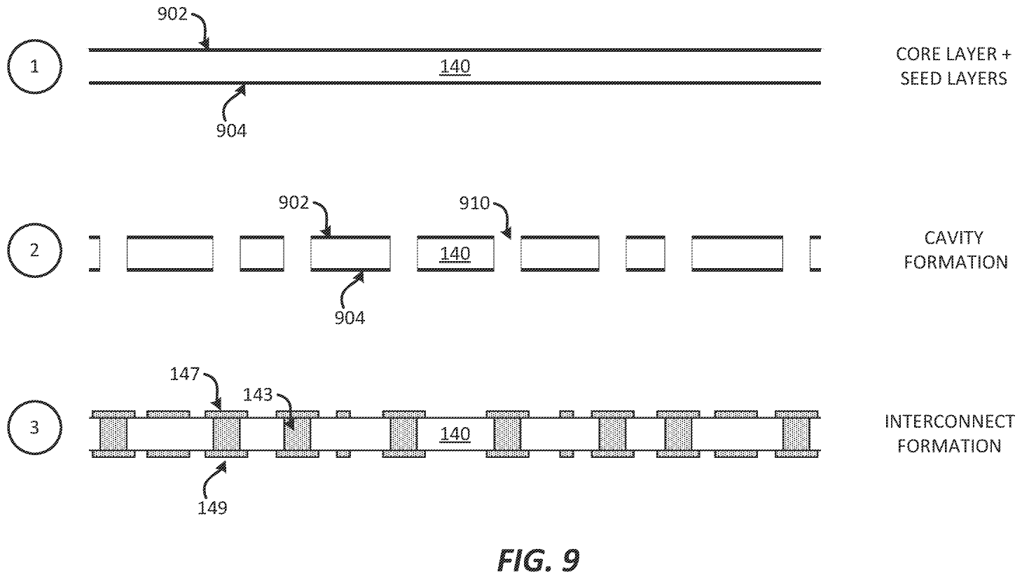

In some implementations, fabricating a cored substrate portion includes several processes. FIG. 9 illustrates an exemplary sequence for providing or fabricating a cored substrate portion. In some implementations, the sequence of FIG. 9 may be used to provide or fabricate the cored substrate portion 104. However, the process of FIG. 9 may be used to fabricate other cored substrate portions described in the disclosure.

It should be noted that the sequence of FIG. 9 may combine one or more stages in order to simplify and/or clarify the sequence for providing or fabricating a cored substrate portion. In some implementations, the order of the processes may be changed or modified. In some implementations, one or more of processes may be replaced or substituted without departing from the scope of the disclosure.

Stage 1, as shown in FIG. 9, illustrates a state after a core layer 140 is provided. The core layer 140 may include a seed layer 902 located on a first surface of the core layer 140 and a seed layer 904 located on a second surface of the core layer 140. The core layer 140 may be a dielectric.

Stage 2 illustrates a state after a plurality of cavities 910 are formed through the core layer 140, the seed layer 902 and the seed layer 904. The plurality of cavities 910 may be formed using an etching process and/or laser process.

Stage 3 illustrates a state after interconnects are formed in and over surfaces of the core layer 140. A plurality of core interconnects 143 may be formed in the plurality of cavities 910. A plurality of interconnects 147 may be formed over (e.g., above) a first surface of the core layer 140. The seed layer 902 may be part of the plurality of interconnects 147. A plurality of interconnects 149 may be formed over (e.g., below) a second surface of the core layer 140. The seed layer 904 may be part of the plurality of interconnects 149. A masking, a plating and/or an etching process may be used to form the plurality of core interconnects 143, the plurality of interconnects 147 and/or the plurality of interconnects 149. Stage 3 may illustrate part of the cored substrate portion 104.

### Exemplary Sequence for Fabricating a Cored Substrate Portion

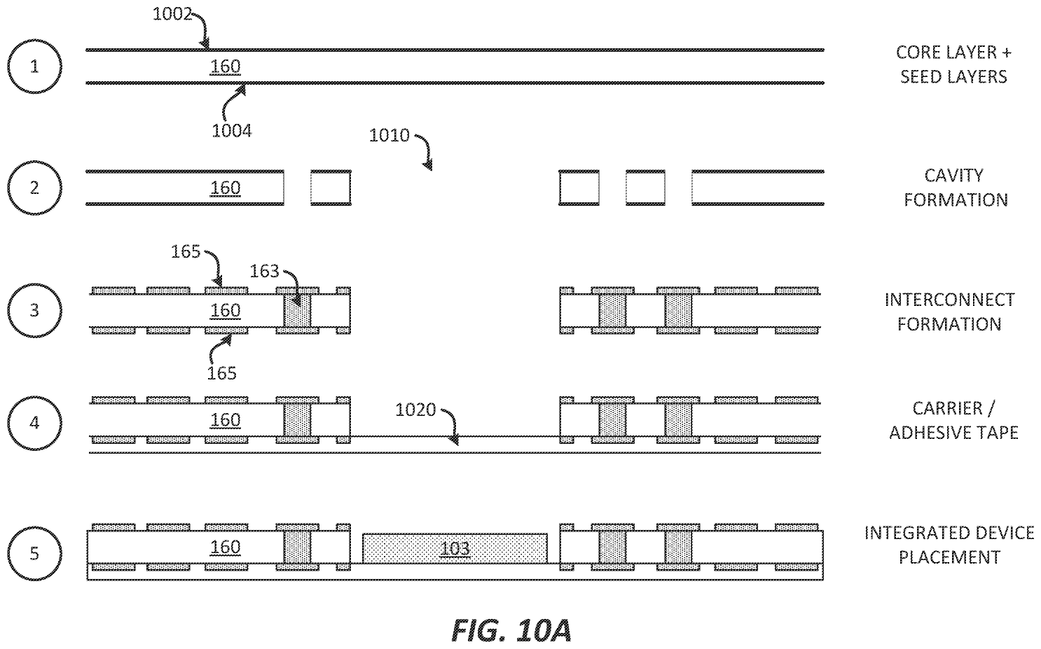

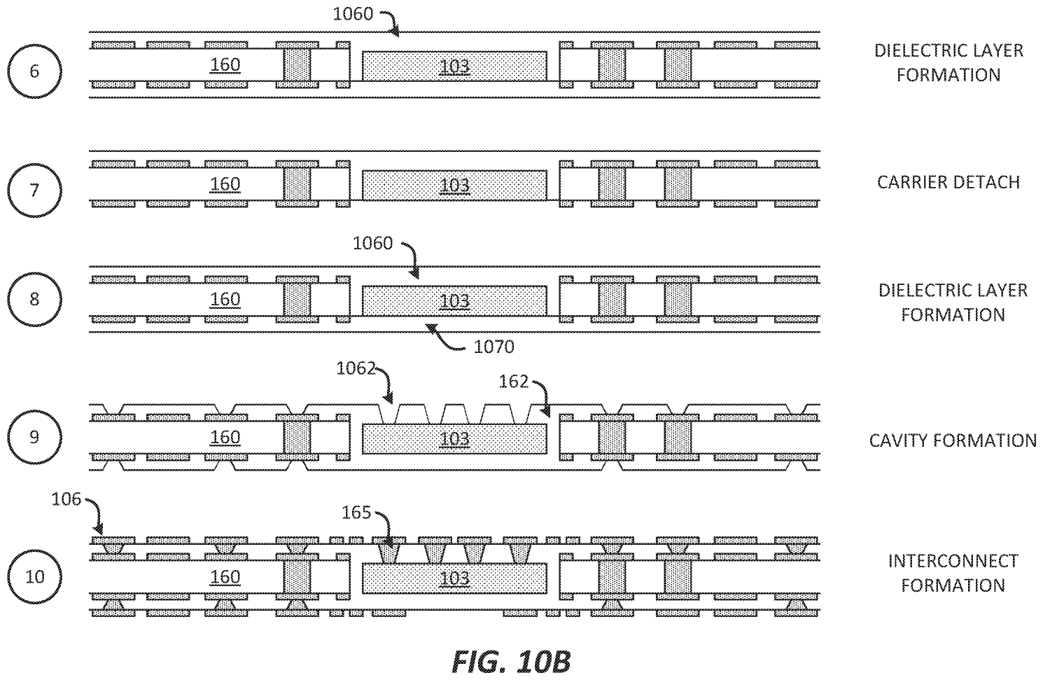

In some implementations, fabricating a cored substrate portion includes several processes. FIGS. 10A-10B illustrate an exemplary sequence for providing or fabricating a cored substrate portion. In some implementations, the sequence of FIGS. 10A-10B may be used to provide or fabricate the cored substrate portion 106. However, the process of FIGS. 10A-10B may be used to fabricate other cored substrate portions described in the disclosure.

It should be noted that the sequence of FIGS. 10A-10B may combine one or more stages in order to simplify and/or clarify the sequence for providing or fabricating a cored substrate portion. In some implementations, the order of the processes may be changed or modified. In some implementations, one or more of processes may be replaced or substituted without departing from the scope of the disclosure.

Stage 1, as shown in FIG. 10A, illustrates a state after a core layer 160 is provided. The core layer 160 may include a seed layer 1002 located on a first surface of the core layer 160 and a seed layer 1004 located on a second surface of the core layer 160. The core layer 160 may be a dielectric.

Stage 2 illustrates a state after a plurality of cavities 1010 are formed through the core layer 160, the seed layer 1002 and the seed layer 1004. The plurality of cavities 1010 may be formed using an etching process and/or laser process.

Stage 3 illustrates a state after interconnects are formed in and over surfaces of the core layer 160. A plurality of core interconnects 163 may be formed in the plurality of cavities 1010. A plurality of interconnects 165 may be formed over (e.g., above) a first surface of the core layer 140. The seed layer 1002 may be part of the plurality of interconnects 165. A plurality of interconnects 165 may be formed over (e.g., below) a second surface of the core layer 160. The seed layer 1004 may be part of the plurality of interconnects 165. A masking, a plating and/or an etching process may be used to form the plurality of core interconnects 163 and/or the plurality of interconnects 165.

Stage 4 illustrates a state after the core layer 160, the plurality of core interconnects 163 and the plurality of interconnects 165 may be placed on and/or coupled to a carrier 1020. The carrier 1020 may include an adhesive.

Stage 5 illustrates a state after an integrated device 103 is placed in the cavity from the plurality of cavities 1010 of the core layer 160. A pick and place process may be used to place the integrated device 103. The integrated device 103 may be placed on and/or coupled to the carrier 1020.

Stage 6, as shown in FIG. 10B, illustrates a state after a dielectric layer 1060 is formed over (e.g., above) the first surface of the core layer 160 and the plurality of interconnects 165. The dielectric layer 1060 may also be formed in the cavity of the core layer 160 that includes the integrated device 103. The dielectric layer 1060 may be coupled to and touch the integrated device 103. The dielectric layer 1060 may touch the side walls of the integrated device 103 and the side wall and/or side surface of the core layer 160. A deposition and/or a lamination process may be used to form the dielectric layer 1060. The dielectric layer 1060 may be a different material than the core layer 160. The dielectric layer 1060 may include prepreg.

Stage 7 illustrates a state after the carrier 1020 is decoupled from the core layer 160 and the dielectric layer 1060. The carrier 1020 may be detached from the core layer 160, the dielectric layer 1060 and the integrated device 103.

Stage 8 illustrates a state after a dielectric layer 1070 is formed over (e.g., below) the second surface of the core layer 160 and the plurality of interconnects 165. The dielectric layer 1070 may also be formed in the cavity of the core layer 160 that includes the integrated device 103. A deposition and/or a lamination process may be used to form the dielectric layer 1070. The dielectric layer 1070 may be coupled to and touch the integrated device 103 and the dielectric layer 1060. The dielectric layer 1070 may include prepreg. The dielectric layer 1070 may include a different material or a same material as the dielectric layer 1060. The dielectric layer 1070 may be a different material than the core layer 160. The dielectric layer 1070 and the dielectric layer 1060 may represented as the dielectric layer 162.

Stage 9 illustrates a state after a plurality of cavities 1062 are formed in the dielectric layer 162. The plurality of cavities 1062 may be formed using an etching process (e.g., photo etching process). A masking, an exposure and/or a development process may be used to form the plurality of cavities 1062.

Stage 10 illustrates a state after interconnects are formed in and over surfaces of the dielectric layer 162. A plurality of interconnects 165 may be formed over (e.g., above) a first surface of the dielectric layer 162 and the plurality of cavities 1062. A masking, a plating and/or an etching process may be used to form the plurality of interconnects 165. Stage 10 may illustrate an example of the cored substrate portion 106.

### Exemplary Sequence for Fabricating a Cored Substrate Portion

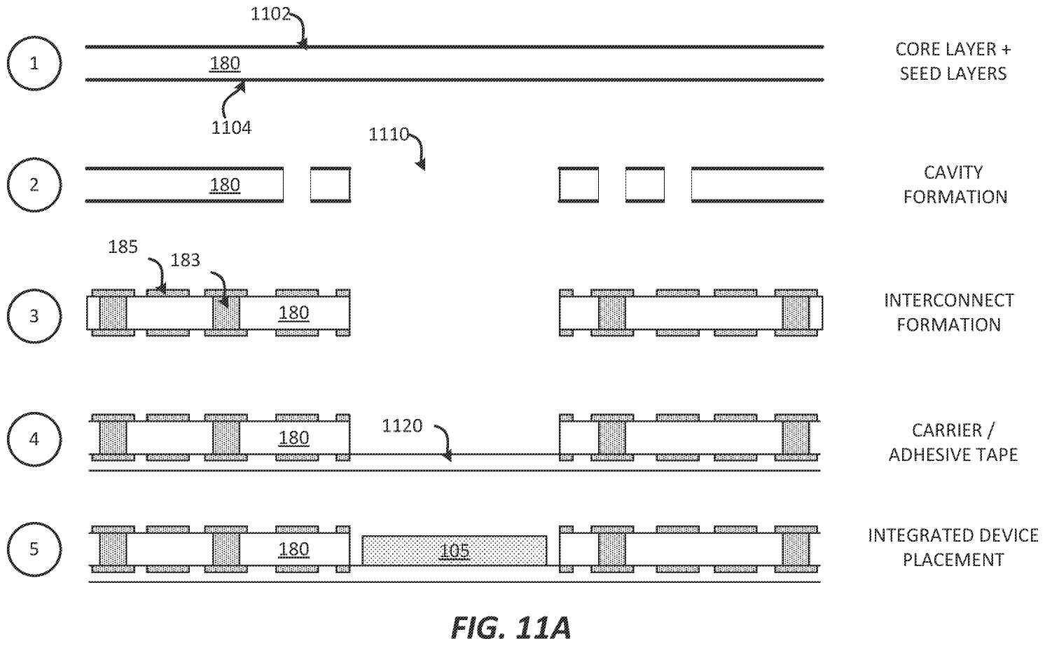

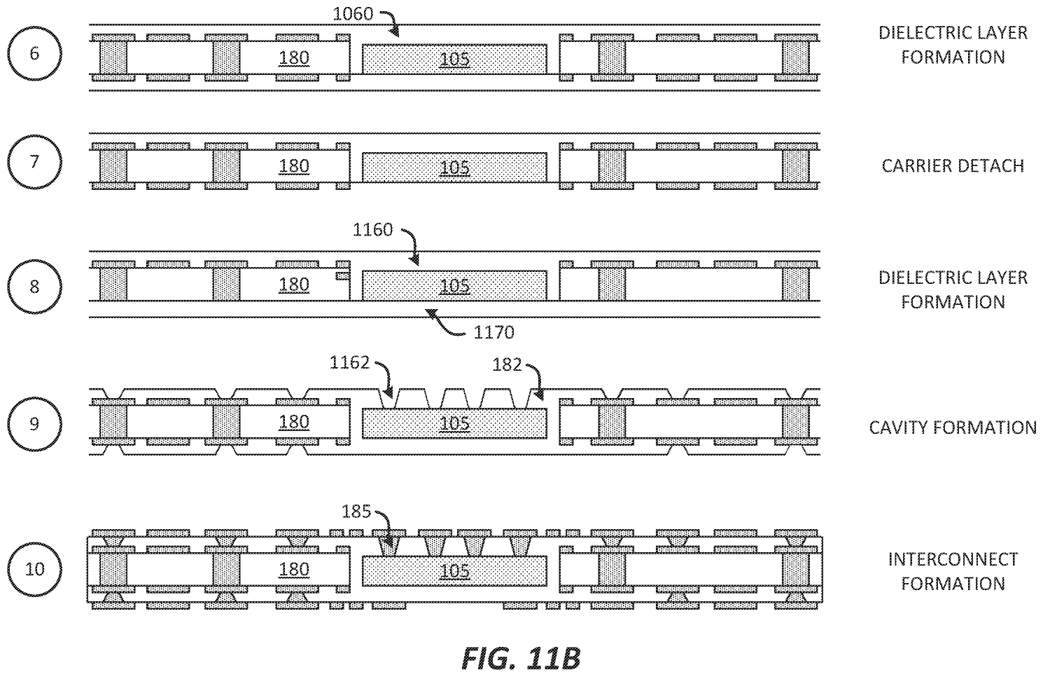

In some implementations, fabricating a cored substrate portion includes several processes. FIGS. 11A-11B illustrate an exemplary sequence for providing or fabricating a cored substrate portion. In some implementations, the sequence of FIGS. 11A-11B may be used to provide or fabricate the cored substrate portion 108. However, the process of FIGS. 11A-11B may be used to fabricate other cored substrate portions described in the disclosure.

It should be noted that the sequence of FIGS. 11A-11B may combine one or more stages in order to simplify and/or clarify the sequence for providing or fabricating a cored substrate portion. In some implementations, the order of the processes may be changed or modified. In some implementations, one or more of processes may be replaced or substituted without departing from the scope of the disclosure.

Stage 1, as shown in FIG. 11A, illustrates a state after a core layer 180 is provided. The core layer 180 may include a seed layer 1102 located on a first surface of the core layer 180 and a seed layer 1104 located on a second surface of the core layer 180. The core layer 180 may be a dielectric.

Stage 2 illustrates a state after a plurality of cavities 1110 are formed through the core layer 180, the seed layer 1102 and the seed layer 1104. The plurality of cavities 1110 may be formed using an etching process and/or laser process.

Stage 3 illustrates a state after interconnects are formed in and over surfaces of the core layer 180. A plurality of core interconnects 163 may be formed in the plurality of cavities 1110. A plurality of interconnects 165 may be formed over (e.g., above) a first surface of the core layer 140. The seed layer 1102 may be part of the plurality of interconnects 165. A plurality of interconnects 165 may be formed over (e.g., below) a second surface of the core layer 180. The seed layer 1104 may be part of the plurality of interconnects 165. A masking, a plating and/or an etching process may be used to form the plurality of core interconnects 163 and/or the plurality of interconnects 165.

Stage 4 illustrates a state after the core layer 180, the plurality of core interconnects 163 and the plurality of interconnects 165 may be placed on and/or coupled to a carrier 1120. The carrier 1120 may include an adhesive.

Stage 5 illustrates a state after an integrated device 105 is placed in the cavity from the plurality of cavities 1110 of the core layer 180. A pick and place process may be used to place the integrated device 105. The integrated device 105 may be placed on and/or coupled to the carrier 1120.

Stage 6, as shown in FIG. 11B, illustrates a state after a dielectric layer 1160 is formed over (e.g., above) the first surface of the core layer 180 and the plurality of interconnects 165. The dielectric layer 1160 may also be formed in the cavity of the core layer 180 that includes the integrated device 105. The dielectric layer 1160 may be coupled to and touch the integrated device 105. The dielectric layer 1160 may touch the side walls of the integrated device 105 and the side wall and/or side surface of the core layer 180. A deposition and/or a lamination process may be used to form the dielectric layer 1160. The dielectric layer 1160 may be a different material than the core layer 180. The dielectric layer 1160 may include prepreg.

Stage 7 illustrates a state after the carrier 1120 is decoupled from the core layer 180 and the dielectric layer 1160. The carrier 1120 may be detached from the core layer 180, the dielectric layer 1160 and the integrated device 105.

Stage 8 illustrates a state after a dielectric layer 1170 is formed over (e.g., below) the second surface of the core layer 180 and the plurality of interconnects 165. The dielectric layer 1170 may also be formed in the cavity of the core layer 180 that includes the integrated device 105. A deposition and/or a lamination process may be used to form the dielectric layer 1170. The dielectric layer 1170 may be coupled to and touch the integrated device 105 and the dielectric layer 1160. The dielectric layer 1170 may include prepreg. The dielectric layer 1170 may include a different material or a same material as the dielectric layer 1160. The dielectric layer 1170 may be a different material than the core layer 180. The dielectric layer 1170 and the dielectric layer 1160 may represented as the dielectric layer 162.

Stage 9 illustrates a state after a plurality of cavities 1162 are formed in the dielectric layer 162. The plurality of cavities 1162 may be formed using an etching process (e.g., photo etching process). A masking, an exposure and/or a development process may be used to form the plurality of cavities 1162.

Stage 10 illustrates a state after interconnects are formed in and over surfaces of the dielectric layer 162. A plurality of interconnects 165 may be formed over (e.g., above) a first surface of the dielectric layer 162 and the plurality of cavities 1162. A masking, a plating and/or an etching process may be used to form the plurality of interconnects 165. Stage 10 may illustrate an example of the cored substrate portion 108.

### Exemplary Flow Diagram of a Method for Fabricating a Cored Substrate/a Cored Substrate Portion

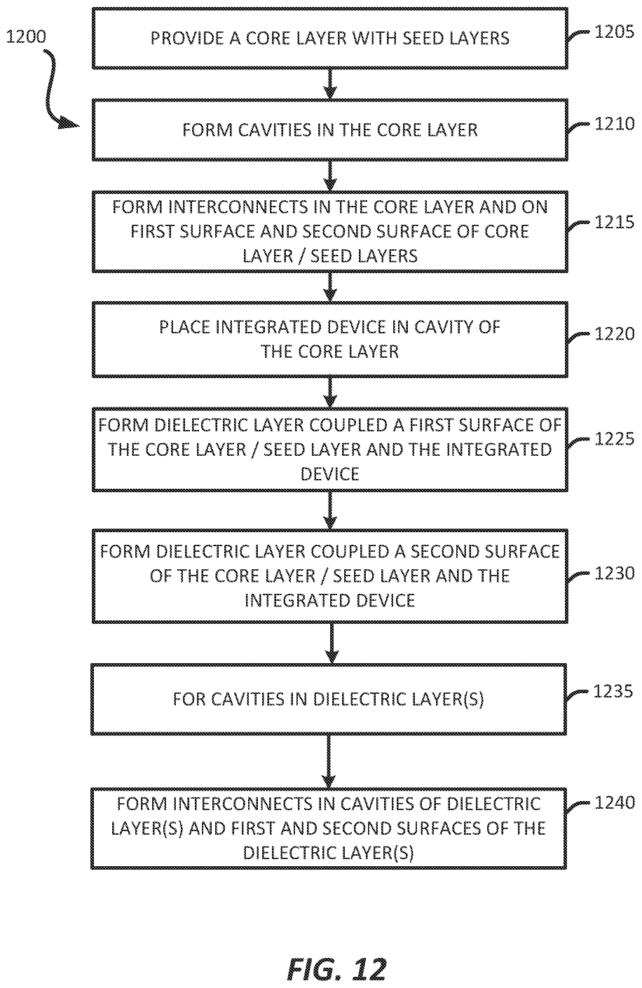

In some implementations, fabricating a cored substrate portion includes several processes. FIG. 12 illustrates an exemplary flow diagram of a method 1200 for providing or fabricating a cored substrate portion. In some implementations, the method 1200 of FIG. 12 may be used to provide or fabricate any of the cored substrate portion of FIGS. 1-9. FIG. 12 will be described with respect to fabricating the cored substrate portion 108. However, FIG. 12 may be used to fabricate any cored substrate portions.

It should be noted that the method 1200 of FIG. 12 may combine one or more processes in order to simplify and/or clarify the method for providing or fabricating a cored substrate portion. In some implementations, the order of the processes may be changed or modified.

The method provides (at 1205) a core layer with seed layers. Stage 1 of FIG. 11A, illustrates and describes an example of a core layer 180 that is provided with seed layers. The core layer 180 may include a seed layer 1102 located on a first surface of the core layer 180 and a seed layer 1104 located on a second surface of the core layer 180. The core layer 180 may be a dielectric.

The method forms (at 1210) cavities in the core layer. Stage 2 of FIG. 11A, illustrates and describes an example of a plurality of cavities 1110 that are formed through the core layer 180, the seed layer 1102 and the seed layer 1104. The plurality of cavities 1110 may be formed using an etching process and/or laser process.

The method forms (at 1215) core interconnects in the core layer and interconnects above and below the core layer. Stage 3 of FIG. 11A, illustrates and describes an example of interconnects that are formed in and over surfaces of the core layer 180. A plurality of core interconnects 163 may be formed in the plurality of cavities 1110. A plurality of interconnects 165 may be formed over (e.g., above) a first surface of the core layer 140. The seed layer 1102 may be part of the plurality of interconnects 165. A plurality of interconnects 165 may be formed over (e.g., below) a second surface of the core layer 180. The seed layer 1104 may be part of the plurality of interconnects 165. A masking, a plating and/or an etching process may be used to form the plurality of core interconnects 163 and/or the plurality of interconnects 165.

The method places (at 1220) an integrated device in a cavity of the core layer. The core layer may be located over a carrier. Stage 4 of FIG. 11A, illustrates and describes an example of the core layer 180, the plurality of core interconnects 163 and the plurality of interconnects 165 that may be placed on and/or coupled to a carrier 1120. The carrier 1120 may include an adhesive. Stage 5 of FIG. 11A, illustrates and describes an example of an integrated device 105 that is placed in the cavity from the plurality of cavities 1110 of the core layer 180. A pick and place process may be used to place the integrated device 105. The integrated device 105 may be placed on and/or coupled to the carrier 1120.

The method forms (at 1225) a dielectric layer that is coupled to a first surface of the core layer and to the integrated device. Stage 6 of FIG. 11B, illustrates and describes an example of a dielectric layer 1160 that is formed over (e.g., above) the first surface of the core layer 180 and the plurality of interconnects 165. The dielectric layer 1160 may also be formed in the cavity of the core layer 180 that includes the integrated device 105. The dielectric layer 1160 may be coupled to and touch the integrated device 105. The dielectric layer 1160 may touch the side walls of the integrated device 105 and the side wall and/or side surface of the core layer 180. A deposition and/or a lamination process may be used to form the dielectric layer 1160. The dielectric layer 1160 may be a different material than the core layer 180. The dielectric layer 1160 may include prepreg.

The method forms (at 1230) another dielectric layer that is coupled to a second surface of the core layer and to the integrated device. Before the dielectric layer is formed, the carrier may be detached. Stage 7 of FIG. 11B, illustrates and describes an example of the carrier 1120 that is decoupled from the core layer 180 and the dielectric layer 1160. The carrier 1120 may be detached from the core layer 180, the dielectric layer 1160 and the integrated device 105. Stage 8 of FIG. 11B, illustrates and describes an example of a dielectric layer 1170 that is formed over (e.g., below) the second surface of the core layer 180 and the plurality of interconnects 165. The dielectric layer 1170 may also be formed in the cavity of the core layer 180 that includes the integrated device 105. A deposition and/or a lamination process may be used to form the dielectric layer 1170. The dielectric layer 1170 may be coupled to and touch the integrated device 105 and the dielectric layer 1160. The dielectric layer 1170 may include prepreg. The dielectric layer 1170 may include a different material or a same material as the dielectric layer 1160. The dielectric layer 1170 may be a different material than the core layer 180. The dielectric layer 1170 and the dielectric layer 1160 may represented as the dielectric layer 162.

The method forms (at 1335) cavities in the dielectric layers. Stage 9 of FIG. 11B, illustrates and describes an example of a plurality of cavities 1162 that are formed in the dielectric layer 162. The plurality of cavities 1162 may be formed using an etching process (e.g., photo etching process). A masking, an exposure and/or a development process may be used to form the plurality of cavities 1162.

The method forms (at 1340) a plurality of interconnects in the dielectric layers and/or over surfaces of the dielectric layers. Stage 10 of FIG. 11B, illustrates and describes an example of interconnects that are formed in and over surfaces of the dielectric layer 162. A plurality of interconnects 165 may be formed over (e.g., above) a first surface of the dielectric layer 162 and the plurality of cavities 1162. A masking, a plating and/or an etching process may be used to form the plurality of interconnects 165.

### Exemplary Sequence for Fabricating a Substrate With at Least Two Core Layers

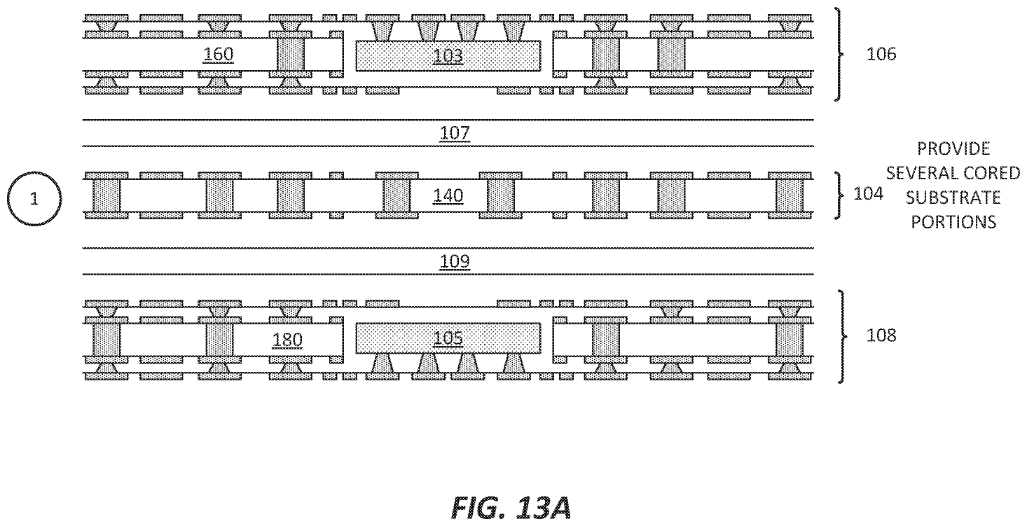

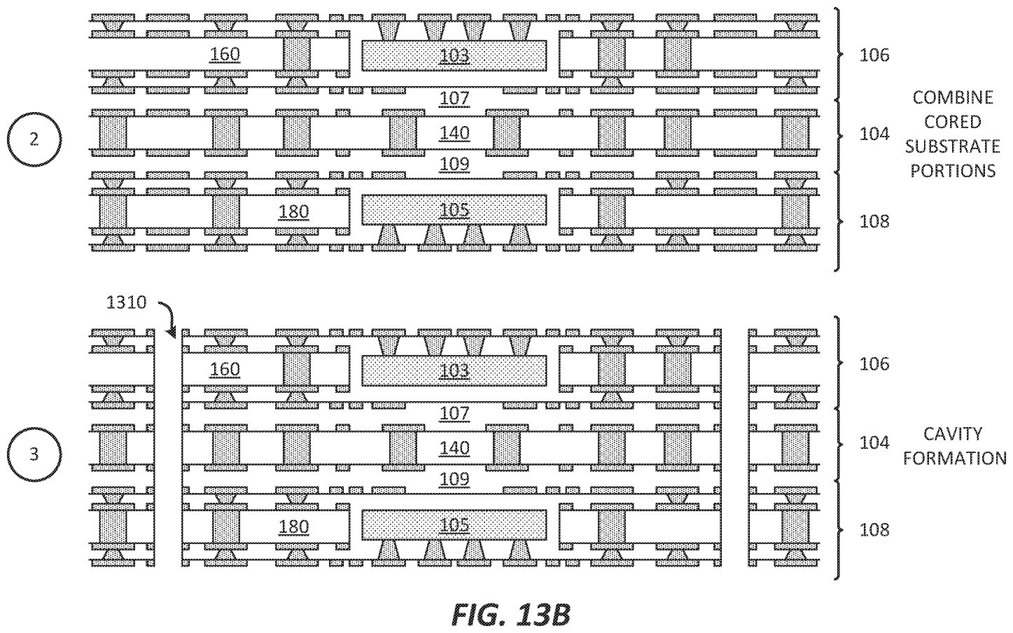

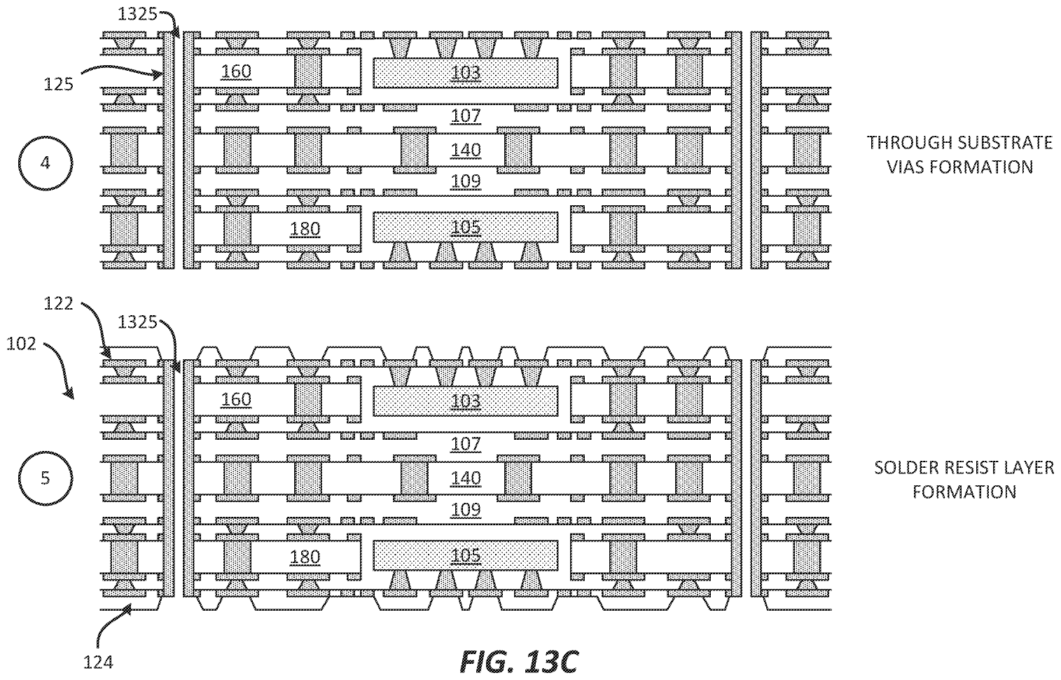

FIGS. 13A-13C illustrate an exemplary sequence for providing or fabricating a substrate. In some implementations, the sequence of FIGS. 13A-13C may be used to provide or fabricate the substrate 102 of FIG. 1, or any of the substrates described in the disclosure.

It should be noted that the sequence of FIGS. 13A-13C may combine one or more stages in order to simplify and/or clarify the sequence for providing or fabricating the substrate. In some implementations, the order of the processes may be changed or modified. In some implementations, one or more of processes may be replaced or substituted without departing from the scope of the disclosure. The sequence of FIGS. 13A-13C may be used to fabricate one substrate or several substrates at a time (as part of a wafer).

Stage 1, as shown in FIG. 13A, illustrates a state after several cored substrate portions and dielectric layers are provided. Examples of cored substrate portions include the cored substrate portion 104, the cored substrate portion 106, the cored substrate portion 108, the dielectric layer 107 and/or the dielectric layer 109. The cored substrate portions may be fabricated, as described in at least FIGS. 10A-10B and/or 11A-11B.

Stage 2, as shown in FIG. 13B, illustrates a state after the cored substrate portion 104, the cored substrate portion 106 and the cored substrate portion 108 are combined. A lamination process may be used to combine the cored substrate portion 104, the cored substrate portion 106 and the cored substrate portion 108. The cored substrate portion 104 may be located between the cored substrate portion 106 and the cored substrate portion 108. The cored substrate portion 106 may be coupled to the cored substrate portion 104 through the dielectric layer 107. The cored substrate portion 108 may be coupled to the cored substrate portion 104 through the dielectric layer 109. The dielectric layer 107 may be considered part of the of the cored substrate portion 106 and/or the part of the cored substrate portion 104. The dielectric layer 109 may be considered part of the of the cored substrate portion 108 and/or the part of the cored substrate portion 104.

Stage 3 illustrates a state after a plurality of cavities 1310 through the cored substrate portion 106, the cored substrate portion 104 and the cored substrate portion 108. A laser process (e.g., laser ablation) may be used to form the plurality of cavities 1310.

Stage 4, as shown in FIG. 13C, illustrates a state after a plurality of via interconnects 125 are formed in the plurality of cavities 1310. A masking, a plating and/or an etching process may be used to form the plurality of via interconnects 125. The plurality of via interconnects 125 may be formed on the side walls of the plurality of cavities 1310. A plurality of cavities 1325 may remain through the plurality of via interconnects 125. The plurality of via interconnects 125 may be a plurality of through substrate vias.

Stage 5 illustrates a state after a solder resist layer 122 and a solder resist layer 124 are formed. The solder resist layer 122 may be formed over (e.g., above) the cored substrate portion 106. The solder resist layer 122 may include openings that expose portions of the plurality of interconnects 165. The solder resist layer 124 may be formed over (e.g., below) the cored substrate portion 108. The solder resist layer 124 may include openings that expose portions of the plurality of interconnects 185. A deposition, lamination, a masking, an exposure and/or a development process may be used to form the solder resist layers and the openings in the solder resist layers.

Once the substrate is fabricated, one or more integrated devices may be coupled to the substrate through a plurality of solder interconnects. A reflow solder process may be used to couple one or more integrated devices to the substrate.

### Exemplary Sequence for Fabricating a Substrate With at Least Two Core Layers

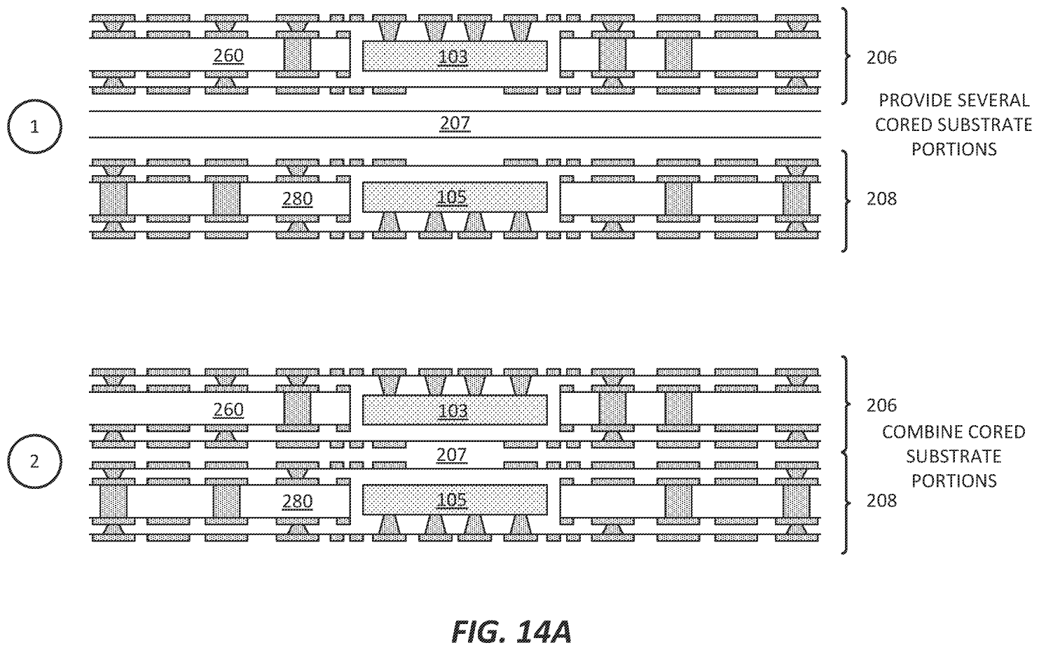

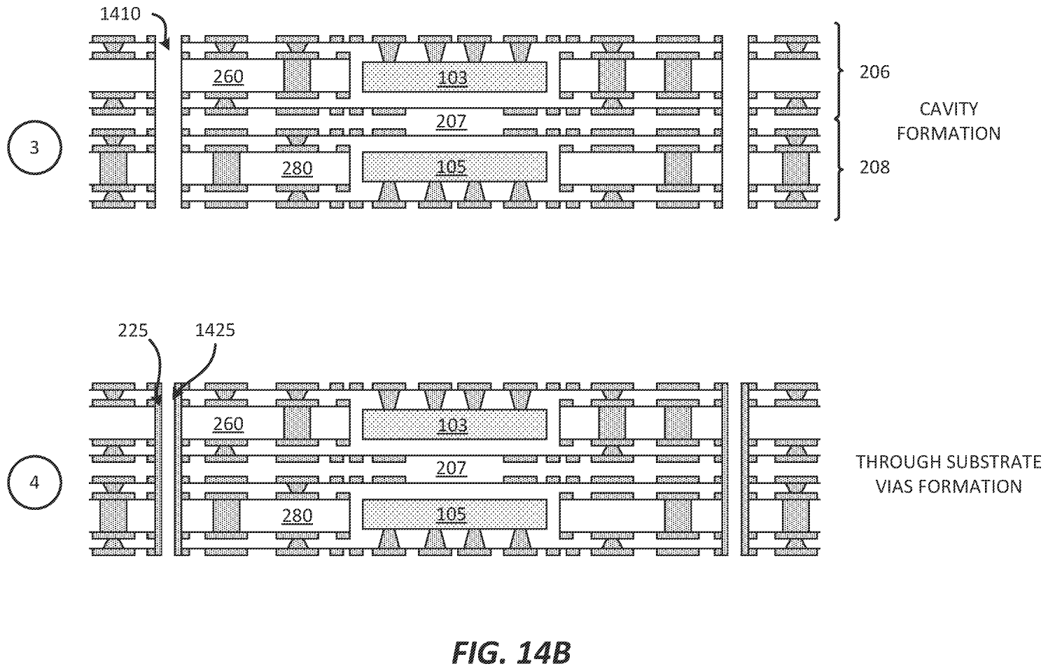

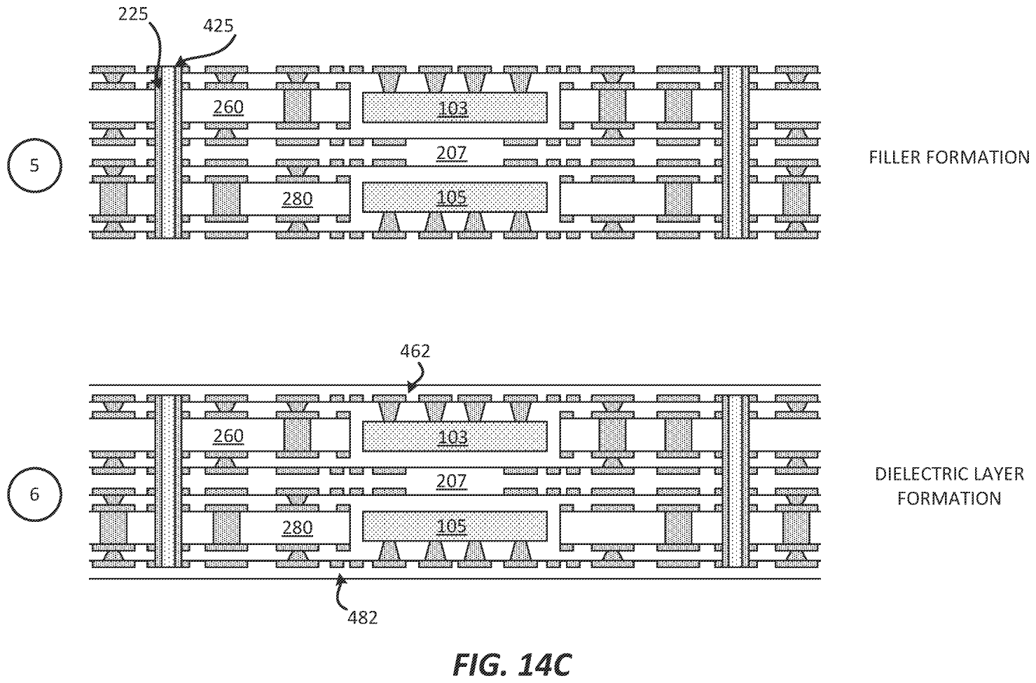

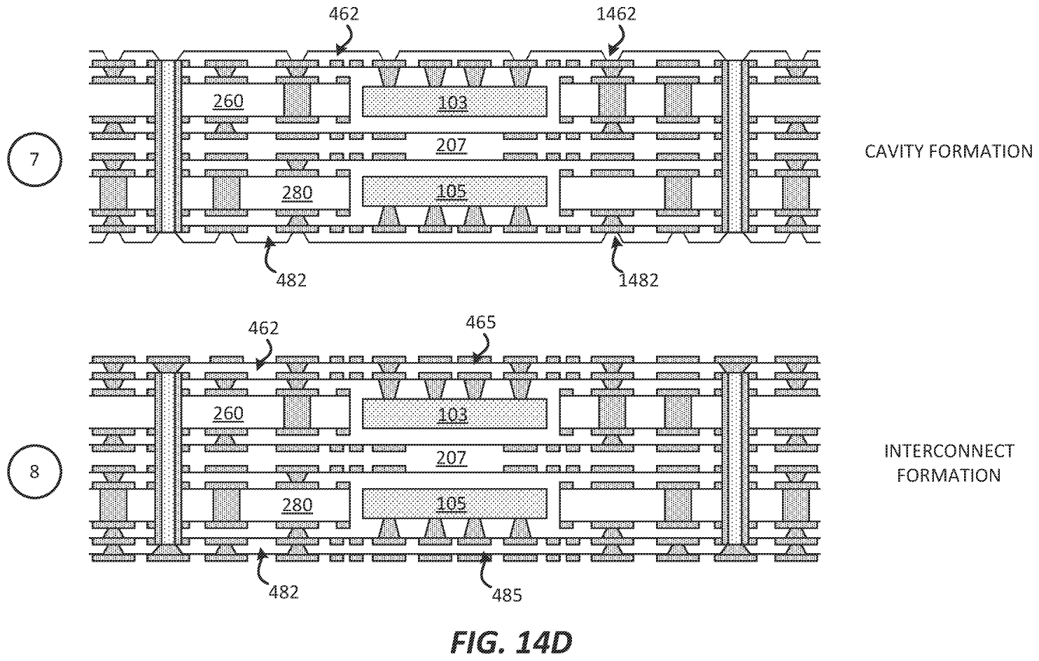

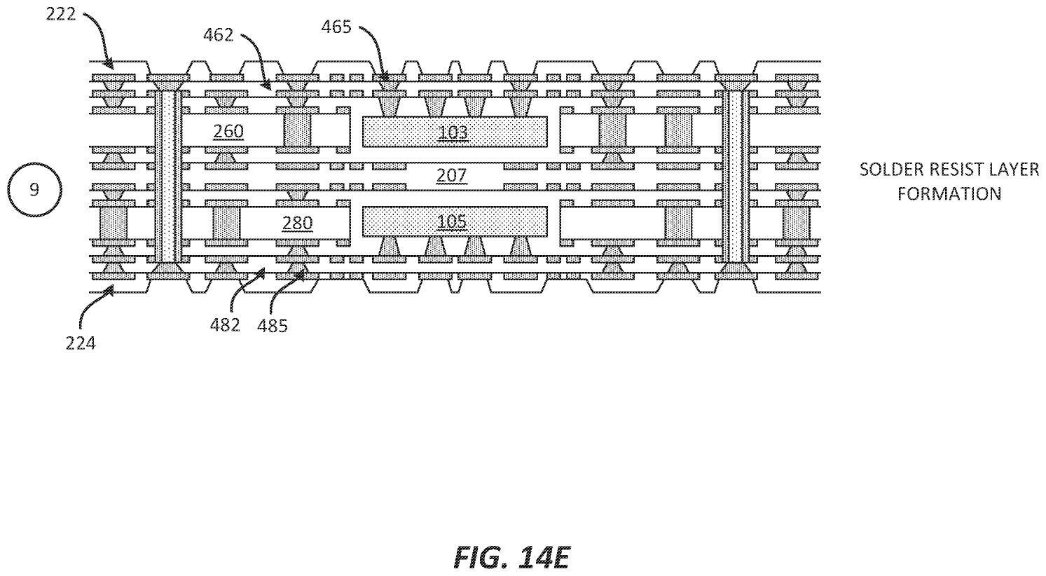

FIGS. 14A-14E illustrate an exemplary sequence for providing or fabricating a substrate. In some implementations, the sequence of FIGS. 14A-14E may be used to provide or fabricate the substrate 402 of FIG. 4, or any of the substrates described in the disclosure.

It should be noted that the sequence of FIGS. 14A-14E may combine one or more stages in order to simplify and/or clarify the sequence for providing or fabricating the substrate. In some implementations, the order of the processes may be changed or modified. In some implementations, one or more of processes may be replaced or substituted without departing from the scope of the disclosure. The sequence of FIGS. 14A-14E may be used to fabricate one substrate or several substrates at a time (as part of a wafer).

Stage 1, as shown in FIG. 14A, illustrates a state after several cored substrate portions and dielectric layers are provided. Examples of cored substrate portions include the cored substrate portion 206, the cored substrate portion 208 and/or the dielectric layer 207. The cored substrate portions may be fabricated, as described in at least FIGS. 10A-10B and/or 11A-11B.

Stage 2 illustrates a state after the cored substrate portion 206 and the cored substrate portion 208 are combined. A lamination process may be used to combine the cored substrate portion 206 and the cored substrate portion 208. The cored substrate portion 206 may be coupled to the cored substrate portion 208 through the dielectric layer 207. The dielectric layer 207 may be considered part of the of the cored substrate portion 206 and/or the part of the cored substrate portion 208.

Stage 3, as shown in FIG. 14B, illustrates a state after a plurality of cavities 1410 through the cored substrate portion 206 and the cored substrate portion 208. A laser process (e.g., laser ablation) may be used to form the plurality of cavities 1410.

Stage 4 illustrates a state after a plurality of via interconnects 225 are formed in the plurality of cavities 1410. A masking, a plating and/or an etching process may be used to form the plurality of via interconnects 225. The plurality of via interconnects 225 may be formed on the side walls of the plurality of cavities 1410. A plurality of cavities 1425 may remain through the plurality of via interconnects 225. The plurality of via interconnects 225 may be a plurality of through substrate vias.

Stage 5, as shown in FIG. 14C, illustrates a state after a filler 425 is formed in the plurality of cavities 1425. The filler 425 may be laterally surrounded by the plurality of via interconnects 225. Different materials may use different materials for the filler 425. The filler 425 may be a dielectric material. The filler 425 may include a mold, a resin and/or an epoxy. A deposition process and/or an injection process may be used to form the filler 425.

Stage 6 illustrates a state after a dielectric layer 462 is formed over (e.g., above) the dielectric layer 162 and the plurality of interconnects 265. A deposition and/or a lamination process may be used to form the dielectric layer 462. The dielectric layer 462 may include a different material or a same material as the dielectric layer 162. Stage 6 also illustrates a state after a dielectric layer 482 is formed over (e.g., below) the dielectric layer 182 and the plurality of interconnects 285. A deposition and/or a lamination process may be used to form the dielectric layer 482. The dielectric layer 482 may include a different material or a same material as the dielectric layer 182.

Stage 7, as shown in FIG. 14D, illustrates a state after a plurality of cavities 1462 are formed in the dielectric layer 462, and a plurality of cavities 1482 are formed in the dielectric layer 482. The plurality of cavities 1462 and/or the plurality of cavities 1482 may be formed using an etching process (e.g., photo etching process). A masking, an exposure and/or a development process may be used to form the plurality of cavities 1462 and/or the plurality of cavities 1482.

Stage 8 illustrates a state after interconnects are formed in and over surfaces of the dielectric layer 462 and/or surfaces of the dielectric layer 482. A plurality of interconnects 465 may be formed over (e.g., above) a first surface of the dielectric layer 462 and the plurality of cavities 1462. A masking, a plating and/or an etching process may be used to form the plurality of interconnects 465. A plurality of interconnects 485 may be formed over (e.g., below) a first surface of the dielectric layer 482 and the plurality of cavities 1482. A masking, a plating and/or an etching process may be used to form the plurality of interconnects 485.

Stage 9, as shown in FIG. 14E, illustrates a state after a solder resist layer 222 and a solder resist layer 224 are formed. The solder resist layer 222 may be formed over (e.g., above) the plurality of interconnects 465 and/or the dielectric layer 462. The solder resist layer 222 may include openings that expose portions of the plurality of interconnects 465. The solder resist layer 224 may be formed over (e.g., below) the plurality of interconnects 485 and/or the dielectric layer 482. The solder resist layer 224 may include openings that expose portions of the plurality of interconnects 485. A deposition, lamination, a masking, an exposure and/or a development process may be used to form the solder resist layers and the openings in the solder resist layers.

Once the substrate is fabricated, one or more integrated devices may be coupled to the substrate through a plurality of solder interconnects. A reflow solder process may be used to couple one or more integrated devices to the substrate.

### Exemplary Flow Diagram of a Method for Fabricating a Substrate With at Least Two Core Layers

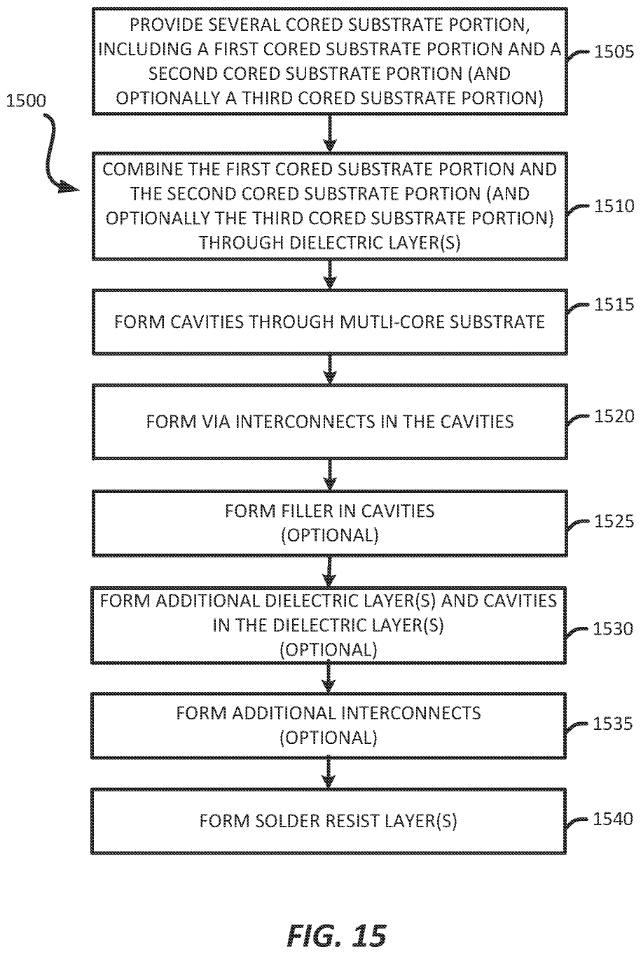

In some implementations, fabricating a cored substrate portion includes several processes. FIG. 15 illustrates an exemplary flow diagram of a method 1500 for providing or fabricating a substrate. In some implementations, the method 1500 of FIG. 15 may be used to provide or fabricate any of the substrates of FIGS. 1-9. FIG. 15 will be described with respect to fabricating the substrate 402. However, FIG. 15 may be used to fabricate any cored substrate portions.

It should be noted that the method 1500 of FIG. 15 may combine one or more processes in order to simplify and/or clarify the method for providing or fabricating a cored substrate portion. In some implementations, the order of the processes may be changed or modified.

The method provides (at 1505) several cored substrate portions and dielectric layers. Stage 1 of FIG. 14A, illustrates and describes an example of several cored substrate portions and dielectric layers that are provided. Examples of cored substrate portions include the cored substrate portion 206, the cored substrate portion 208 and/or the dielectric layer 207. In some implementations, more than two cored substrate portions are provided, such as cored substrate portion 104, cored substrate portion 106 and cored substrate portion 108. The cored substrate portions may be fabricated, as described in at least FIGS. 10A-10B and/or 11A-11B.

The method combines (at 1510) the cored substrate portion through one or more dielectric layers. Stage 2 of FIG. 14A, illustrates and describes an example of a cored substrate portion 206 and the cored substrate portion 208 that are combined. A lamination process may be used to combine the cored substrate portion 206 and the cored substrate portion 208. The cored substrate portion 206 may be coupled to the cored substrate portion 208 through the dielectric layer 207. The dielectric layer 207 may be considered part of the of the cored substrate portion 206 and/or the part of the cored substrate portion 208.

The method forms (at 1515) a plurality of cavities. Stage 3 of FIG. 14B. illustrates and describes an example of a plurality of cavities 1410 that are formed through the cored substrate portion 206 and the cored substrate portion 208. A laser process (e.g., laser ablation) may be used to form the plurality of cavities 1410.

The method forms (at 1520) a plurality of via interconnects in the plurality of cavities. Stage 4 of FIG. 14B, illustrates and describes an example of a plurality of via interconnects 225 that are formed in the plurality of cavities 1410. A masking, a plating and/or an etching process may be used to form the plurality of via interconnects 225. The plurality of via interconnects 225 may be formed on the side walls of the plurality of cavities 1410. A plurality of cavities 1425 may remain through the plurality of via interconnects 225.

The method optionally forms (at 1525) a filler in the plurality of cavities. Stage 5 of FIG. 14C, illustrates and describes an example of a filler 425 that is formed in the plurality of cavities 1425. The filler 425 may be laterally surrounded by the plurality of via interconnects 225. Different materials may use different materials for the filler 425. The filler 425 may be a dielectric material. The filler 425 may include a mold, a resin and/or an epoxy. A deposition process and/or an injection process may be used to form the filler 425.

The method optionally forms (at 1530) one or more dielectric layers. Stage 6 of FIG. 14C, illustrates and describes an example of a dielectric layer 462 that is formed over (e.g., above) the dielectric layer 162 and the plurality of interconnects 265. A deposition and/or a lamination process may be used to form the dielectric layer 462. The dielectric layer 462 may include a different material or a same material as the dielectric layer 162. Stage 6 also illustrates and describes an example of a dielectric layer 482 that is formed over (e.g., below) the dielectric layer 182 and the plurality of interconnects 285. A deposition and/or a lamination process may be used to form the dielectric layer 482. The dielectric layer 482 may include a different material or a same material as the dielectric layer 182.

The method optionally forms (at 1530) a plurality of cavities in the dielectric layer(s). Stage 7 of FIG. 14D, illustrates and describes an example of a plurality of cavities 1462 that are formed in the dielectric layer 462, and a plurality of cavities 1482 are formed in the dielectric layer 482. The plurality of cavities 1462 and/or the plurality of cavities 1482 may be formed using an etching process (e.g., photo etching process). A masking, an exposure and/or a development process may be used to form the plurality of cavities 1462 and/or the plurality of cavities 1482.

The method optionally forms (at 1535) a plurality of interconnects. Stage 8 of FIG. 14D, illustrates and describes an example of interconnects that are formed in and over surfaces of the dielectric layer 462 and/or surfaces of the dielectric layer 482. A plurality of interconnects 465 may be formed over (e.g., above) a first surface of the dielectric layer 462 and the plurality of cavities 1462. A masking, a plating and/or an etching process may be used to form the plurality of interconnects 465. A plurality of interconnects 485 may be formed over (e.g., below) a first surface of the dielectric layer 482 and the plurality of cavities 1482. A masking, a plating and/or an etching process may be used to form the plurality of interconnects 485.

The method optionally forms (at 1540) one or more solder resist layers. Stage 9 of FIG. 14E, illustrates and describes an example of a solder resist layer 222 and a solder resist layer 224 that are formed. The solder resist layer 222 may be formed over (e.g., above) the plurality of interconnects 465 and/or the dielectric layer 462. The solder resist layer 222 may include openings that expose portions of the plurality of interconnects 465. The solder resist layer 224 may be formed over (e.g., below) the plurality of interconnects 485 and/or the dielectric layer 482. The solder resist layer 224 may include openings that expose portions of the plurality of interconnects 485. A deposition, lamination, a masking, an exposure and/or a development process may be used to form the solder resist layers and the openings in the solder resist layers.

Once the substrate is fabricated, one or more integrated devices may be coupled to the substrate through a plurality of solder interconnects. A reflow solder process may be used to couple one or more integrated devices to the substrate.

### Exemplary Electronic Devices

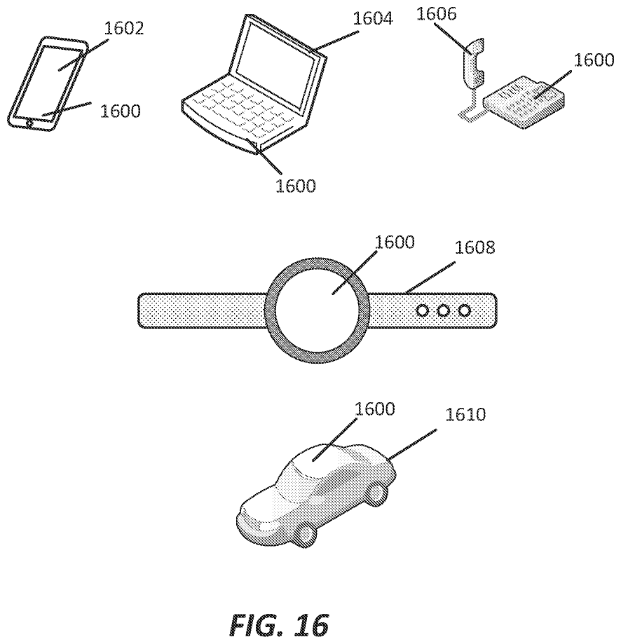

FIG. 16 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1602, a laptop computer device 1604, a fixed location terminal device 1606, a wearable device 1608, or automotive vehicle 1610 may include a device 1600 as described herein. The device 1600 may be, for example, any of the devices and/or integrated circuit (IC) packages described herein. The devices 1602, 1604, 1606 and 1608 and the vehicle 1610 illustrated in FIG. 16 are merely exemplary. Other electronic devices may also feature the device 1600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-9, 10A-10B, 11A-11B, 12, 13A-13C, 14A-14E and/or 15-16 may be rearranged and/or combined into a single component, process, feature or function or embodied in several components, processes, or functions. Additional elements, components, processes, and/or functions may also be added without departing from the disclosure. It should also be noted FIGS. 1-9, 10A-10B, 11A-11B, 12, 13A-13C, 14A-14E and/or 15-16 and its corresponding description in the present disclosure is not limited to dies and/or ICs. In some implementations, FIGS. 1-9, 10A-10B, 11A-11B, 12, 13A-13C, 14A-14E and/or 15-16 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. An interconnect may include one or more metal components (e.g., seed layer+metal layer). In some implementations, an interconnect is an electrically conductive material that may be configured to provide an electrical path for a current (e.g., a data signal, ground or power). An interconnect may be part of a circuit. An interconnect may include more than one element or component. An interconnect may be defined by one or more interconnects. Different implementations may use similar or different processes to form the interconnects. In some implementations, a chemical vapor deposition (CVD) process and/or a physical vapor deposition (PVD) process for forming the interconnects. For example, a sputtering process, a spray coating, and/or an electro plating process or electroless plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A substrate comprising a first cored substrate portion and a second cored substrate portion. The first cored substrate portion comprises a first core layer comprising a first cavity; a first integrated device located in the first cavity of the first core layer; and a first dielectric layer encapsulating the first integrated device. The second cored substrate portion comprises a second core layer comprising a second cavity; a second integrated device located in the second cavity of the second core layer; and a second dielectric layer encapsulating the second integrated device.

Aspect 2: The substrate of aspect 1, further comprising a plurality of through substrate vias extending through the first cored substrate portion and the second cored substrate portion.

Aspect 3: The substrate of aspect 2, wherein the first cored substrate portion comprises a first plurality of interconnects, and wherein the second cored substrate portion comprises a second plurality of interconnects.

Aspect 4: The substrate of aspect 3, wherein the first plurality of interconnects comprises: a first plurality of core interconnects located in the first core layer; and a third plurality of interconnects located at least in the first dielectric layer, wherein the second plurality of interconnects comprises: a second plurality of core interconnects located in the second core layer; and a fourth plurality of interconnects located at least in the second dielectric layer.

Aspect 5: The substrate of aspects 3 through 4, wherein the first plurality of interconnects are configured to be electrically coupled to the second plurality of interconnects through the plurality of through substrate vias.

Aspect 6: The substrate of aspects 1 through 5, further comprising: a first metallization portion coupled to the first cored substrate portion; and a second metallization portion coupled to the second cored substrate portion, wherein the first integrated device comprises a first front side and a first back side, wherein the second integrated device comprises a second front side and a second back side, wherein the first back side of the first integrated device faces a first direction, and wherein the second back side of the second integrated device faces a second direction that is opposite to the first direction.

Aspect 7: The substrate of aspects 1 through 6, wherein the first cored substrate portion is coupled to the second cored substrate portion through a third dielectric layer.

Aspect 8: The substrate of aspects 1 through 7, further comprising a third core layer located between the first core layer and the second core layer.

Aspect 9: The substrate of aspect 8, wherein the first cored substrate portion is coupled to the third core layer through a third dielectric layer, and wherein the second cored substrate portion is coupled to the third core layer through a second dielectric layer.

Aspect 10: The substrate of aspects 8 through 9, further comprising a plurality of through substrate vias extending through the first cored substrate portion, the third core layer and the second cored substrate portion.

Aspect 11: The substrate of aspect 10, wherein the first cored substrate portion comprises a first plurality of interconnects, wherein the second cored substrate portion comprises a second plurality of interconnects.

Aspect 12: The substrate of aspect 11, further comprising a third plurality of interconnects located between the first cored substrate portion and the second cored substrate portion.

Aspect 13: The substrate of aspect 12, wherein the first plurality of interconnects are configured to be electrically coupled to the second plurality of interconnects through the plurality of through substrate vias and/or the third plurality of interconnects.

Aspect 14: A package comprising a substrate comprising that includes a first cored substrate portion and a second cored substrate portion. The first cored substrate portion comprises a first core layer comprising a first cavity; a first integrated device located in the first cavity of the first core layer; and a first dielectric layer encapsulating the first integrated device. The second cored substrate portion comprises a second core layer comprising a second cavity; a second integrated device located in the second cavity of the second core layer; and a second dielectric layer encapsulating the second integrated device. The package includes a third integrated device coupled to the substrate through a plurality of solder interconnects.

Aspect 15: The package of aspect 14, further comprising a plurality of through substrate vias extending through the first cored substrate portion and the second cored substrate portion.

Aspect 16: The package of aspect 15, wherein the first cored substrate portion comprises a first plurality of interconnects, and wherein the second cored substrate portion comprises a second plurality of interconnects.

Aspect 17: The package of aspect 16, wherein the first plurality of interconnects comprises: a first plurality of core interconnects located in the first core layer; and a third plurality of interconnects located at least in the first dielectric layer, wherein the second plurality of interconnects comprises: a second plurality of core interconnects located in the second core layer; and a fourth plurality of interconnects located at least in the second dielectric layer.

Aspect 18: The package of aspects 16 through 17, wherein the first plurality of interconnects are configured to be electrically coupled to the second plurality of interconnects through the plurality of through substrate vias.

Aspect 19: The package of aspects 14 through 18, further comprising a first metallization portion coupled to the first cored substrate portion; and a second metallization portion coupled to the second cored substrate portion.

Aspect 20: The package of aspects 14 through 19, wherein the first cored substrate portion is coupled to the second cored substrate portion through a third dielectric layer.

Aspect 21: The package of aspects 14 through 20, further comprising a third core layer located between the first core layer and the second core layer.

Aspect 22: The package of aspect 21, wherein the first cored substrate portion is coupled to the third core layer through a first dielectric layer, and wherein the second cored substrate portion is coupled to the third core layer through a second dielectric layer.

Aspect 23: The package of aspects 21 through 22, further comprising a plurality of through substrate vias extending through the first cored substrate portion, the third core layer and the second cored substrate portion.

Aspect 24: The package of aspect 23, wherein the first cored substrate portion comprises a first plurality of interconnects, wherein the second cored substrate portion comprises a second plurality of interconnects.

Aspect 25: The package of aspect 24, further comprising a third plurality of interconnects located between the first cored substrate portion and the second cored substrate portion.

Aspect 26: The package of aspects 14 through 25, further comprising a fourth integrated device coupled to the substrate through a second plurality of solder interconnects, wherein the first integrated device is a first chiplet, wherein the second integrated device is a second chiplet, and wherein the third integrated device is a third chiplet, and wherein the fourth integrated device is a fourth chiplet.

Aspect 27: A method to fabricate a substrate. Fabricating the substrate comprises providing a first cored substrate portion comprising: a first core layer comprising a first cavity; a first integrated device located in the first cavity of the first core layer; and a first dielectric layer encapsulating the first integrated device. Fabricating the substrate comprises providing a second cored substrate portion comprising: a second core layer comprising a second cavity; a second integrated device located in the second cavity of the second core layer; and a second dielectric layer encapsulating the second integrated device. Fabricating the substrate comprises providing a third dielectric layer. Fabricating the substrate comprises coupling the first cored substrate, the third dielectric layer and the second cored substrate.

Aspect 28: The method of aspect 27, wherein fabricating the substrate further comprises a plurality of through substrate vias extending through the first cored substrate portion and the second cored substrate portion.

Aspect 29: The method of aspect 28, wherein the first cored substrate portion comprises a first plurality of interconnects, and wherein the second cored substrate portion comprises a second plurality of interconnects.

Aspect 30: The method of aspect 29, wherein the first plurality of interconnects comprises: a first plurality of core interconnects located in the first core layer; and a third plurality of interconnects located at least in the first dielectric layer, and wherein the second plurality of interconnects comprises: a second plurality of core interconnects located in the second core layer; and a fourth plurality of interconnects located at least in the second dielectric layer.

Aspect 31: The method of aspect 29, wherein the first plurality of interconnects are configured to be electrically coupled to the second plurality of interconnects through the plurality of through substrate vias.

Aspect 32: The method of aspects 27 through 31, wherein fabricating the substrate further comprises: forming a first metallization portion coupled to the first cored substrate portion; and forming a second metallization portion coupled to the second cored substrate portion, wherein the first integrated device comprises a first front side and a first back side, wherein the second integrated device comprises a second front side and a second back side, wherein the first back side of the first integrated device faces a first direction, and wherein the second back side of the second integrated device faces a second direction that is opposite to the first direction.

Aspect 33: The method of aspects 27 through 32, wherein a lamination process is used to couple the first cored substrate, the third dielectric layer and the second cored substrate.

Aspect 34: The method of aspects 27 through 33, further comprising coupling a third integrated device to the substrate through a first plurality of solder interconnects.

Aspect 35: A method to fabricate a substrate. Fabricating the substrate comprises providing a first cored substrate portion comprising: a first core layer comprising a first cavity; a first integrated device located in the first cavity of the first core layer; and a first dielectric layer encapsulating the first integrated device. Fabricating the substrate comprises providing a second cored substrate portion comprising: a second core layer comprising a second cavity; a second integrated device located in the second cavity of the second core layer; and a second dielectric layer encapsulating the second integrated device. Fabricating the substrate comprises providing a third cored substrate portion comprising a third core layer and a plurality of core interconnects. Fabricating the substrate comprises providing a third dielectric layer and a fourth dielectric layer. Fabricating the substrate comprises coupling the first cored substrate, the third dielectric layer, the third cored substrate portion, the fourth dielectric layer and the second cored substrate.

Aspect 36: The method of aspect 35, wherein fabricating the substrate further comprises a plurality of through substrate vias extending through the first cored substrate portion, the third cored substrate and the second cored substrate portion.

Aspect 37: The method of aspect 36, wherein the first cored substrate portion comprises a first plurality of interconnects, and wherein the second cored substrate portion comprises a second plurality of interconnects.

Aspect 38: The method of aspect 37,wherein the first plurality of interconnects comprises: a first plurality of core interconnects located in the first core layer; and a third plurality of interconnects located at least in the first dielectric layer, and wherein the second plurality of interconnects comprises: a second plurality of core interconnects located in the second core layer; and a fourth plurality of interconnects located at least in the second dielectric layer.

Aspect 39: The method of aspect 37, wherein the first plurality of interconnects are configured to be electrically coupled to the second plurality of interconnects through the plurality of through substrate vias.

Aspect 40: The method of aspects 35 through 39, wherein fabricating the substrate further comprises: forming a first metallization portion coupled to the first cored substrate portion; and forming a second metallization portion coupled to the second cored substrate portion, wherein the first integrated device comprises a first front side and a first back side, wherein the second integrated device comprises a second front side and a second back side, wherein the first back side of the first integrated device faces a first direction, and wherein the second back side of the second integrated device faces a second direction that is opposite to the first direction.

Aspect 41: The method of aspects 35 through 40, wherein a lamination process is used to couple the first cored substrate, the third dielectric layer, the third cored substrate portion, the fourth dielectric layer and the second cored substrate.

Aspect 42: The method of aspects 35 through 41, further comprising coupling a third integrated device to the substrate through a first plurality of solder interconnects.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the aspects. As such, the present teachings can be readily applied to other types of apparatuses and many alternatives, modifications, and variations will be apparent to those skilled in the art.

1. A substrate comprising:
(i) a first cored substrate portion comprising:
a first core layer comprising a first cavity;
a first integrated device located in the first cavity of the first core layer; and
a first dielectric layer encapsulating the first integrated device; and
(ii) a second cored substrate portion comprising:
a second core layer comprising a second cavity;
a second integrated device located in the second cavity of the second core layer; and
a second dielectric layer encapsulating the second integrated device.

2. The substrate of claim 1, further comprising a plurality of through substrate vias extending through the first cored substrate portion and the second cored substrate portion.

3. The substrate of claim 2,
wherein the first cored substrate portion comprises a first plurality of interconnects, and
wherein the second cored substrate portion comprises a second plurality of interconnects.

4. The substrate of claim 3,
wherein the first plurality of interconnects comprises:
a first plurality of core interconnects located in the first core layer; and
a third plurality of interconnects located at least in the first dielectric layer, and
wherein the second plurality of interconnects comprises:
a second plurality of core interconnects located in the second core layer; and
a fourth plurality of interconnects located at least in the second dielectric layer.

5. The substrate of claim 3, wherein the first plurality of interconnects are configured to be electrically coupled to the second plurality of interconnects through the plurality of through substrate vias.

6. The substrate of claim 1, further comprising:
a first metallization portion coupled to the first cored substrate portion; and
a second metallization portion coupled to the second cored substrate portion,
wherein the first integrated device comprises a first front side and a first back side,
wherein the second integrated device comprises a second front side and a second back side,
wherein the first back side of the first integrated device faces a first direction, and
wherein the second back side of the second integrated device faces a second direction that is opposite to the first direction.

7. The substrate of claim 1, wherein the first cored substrate portion is coupled to the second cored substrate portion through a third dielectric layer.

8. The substrate of claim 1, further comprising a third core layer located between the first core layer and the second core layer.

9. The substrate of claim 8,
wherein the first cored substrate portion is coupled to the third core layer through a third dielectric layer, and
wherein the second cored substrate portion is coupled to the third core layer through a second dielectric layer.

10. The substrate of claim 8, further comprising a plurality of through substrate vias extending through the first cored substrate portion, the third core layer and the second cored substrate portion.

11. The substrate of claim 10,
wherein the first cored substrate portion comprises a first plurality of interconnects, and
wherein the second cored substrate portion comprises a second plurality of interconnects.

12. The substrate of claim 11, further comprising a third plurality of interconnects located between the first cored substrate portion and the second cored substrate portion.

13. The substrate of claim 12, wherein the first plurality of interconnects are configured to be electrically coupled to the second plurality of interconnects through the plurality of through substrate vias and/or the third plurality of interconnects.

14. A package comprising:
a substrate comprising:
(i) a first cored substrate portion comprising:
a first core layer comprising a first cavity;
a first integrated device located in the first cavity of the first core layer; and
a first dielectric layer encapsulating the first integrated device; and
(ii) a second cored substrate portion comprising:
a second core layer comprising a second cavity;
a second integrated device located in the second cavity of the second core layer; and
a second dielectric layer encapsulating the second integrated device; and
a third integrated device coupled to the substrate through a plurality of solder interconnects.

15. The package of claim 14, further comprising a plurality of through substrate vias extending through the first cored substrate portion and the second cored substrate portion.

16. The package of claim 15,
wherein the first cored substrate portion comprises a first plurality of interconnects, and
wherein the second cored substrate portion comprises a second plurality of interconnects.

17. The package of claim 16,
wherein the first plurality of interconnects comprises:
a first plurality of core interconnects located in the first core layer; and
a third plurality of interconnects located at least in the first dielectric layer, and
wherein the second plurality of interconnects comprises:
a second plurality of core interconnects located in the second core layer; and
a fourth plurality of interconnects located at least in the second dielectric layer.

18. The package of claim 16, wherein the first plurality of interconnects are configured to be electrically coupled to the second plurality of interconnects through the plurality of through substrate vias.

19. The package of claim 14, further comprising:
a first metallization portion coupled to the first cored substrate portion; and
a second metallization portion coupled to the second cored substrate portion.

20. The package of claim 14, wherein the first cored substrate portion is coupled to the second cored substrate portion through a third dielectric layer.

21. The package of claim 14, further comprising a third core layer located between the first core layer and the second core layer.

22. The package of claim 21,
wherein the first cored substrate portion is coupled to the third core layer through a first dielectric layer, and
wherein the second cored substrate portion is coupled to the third core layer through a second dielectric layer.

23. The package of claim 21, further comprising a plurality of through substrate vias extending through the first cored substrate portion, the third core layer and the second cored substrate portion.

24. The package of claim 23,
wherein the first cored substrate portion comprises a first plurality of interconnects, and
wherein the second cored substrate portion comprises a second plurality of interconnects.

25. The package of claim 24, further comprising a third plurality of interconnects located between the first cored substrate portion and the second cored substrate portion.

26. The package of claim 14, further comprising a fourth integrated device coupled to the substrate through a second plurality of solder interconnects,
wherein the first integrated device is a first chiplet,
wherein the second integrated device is a second chiplet,
wherein the third integrated device is a third chiplet, and
wherein the fourth integrated device is a fourth chiplet.
